(19) United States
(12) Patent Application Publication
(10) Pub. No.: US 2026/0371734 A1
(43) Pub. Date: Nov. 19, 2026

(54) ARRAY SUBSTRATE AND DISPLAY DEVICE

(71) Applicant: SHARP KABUSHIKI KAISHA, Sakai City (JP)

(72) Inventors: Seiichi Uchida, Sakai City (JP); Kuniaki Okada, Sakai City (JP)

(21) Appl. No.: 19/673,137

(22) Filed: May 11, 2026

(30) Foreign Application Priority Data
May 13, 2025 (JP) 2025-080538

(51) Int. Cl. H10D 86/40; G02F 1/1333; G02F 1/1343; G02F 1/1362

(52) U.S. Cl. CPC H10D 86/441; G02F 1/133305; G02F 1/133345; G02F 1/134309; G02F 1/136286

(57) ABSTRACT

An array substrate includes a semiconductor portion, a first insulating film, a first wiring line, a second insulating film, and a first electrode. The first electrode is disposed at a position spaced apart from the first wiring line in a first direction in such a manner that at least a portion of the first electrode overlaps a portion of the semiconductor portion, a first contact hole connecting the semiconductor portion and the first electrode is provided at a position overlapping both the semiconductor portion and the first electrode in the first insulating film and the second insulating film, and the first wiring line includes a first bent portion that is bent to be recessed toward the first contact hole in a plan view so that a portion of the first wiring line overlaps the first contact hole in the first direction.

### CROSS-REFERENCE TO RELATED APPLICATIONS

This application claims the benefit of priority to Japanese Patent Application Number 2025-080538 filed on May 13, 2025. The entire contents of the above-identified application are hereby incorporated by reference.

### BACKGROUND

### Technical Field

The techniques disclosed in this specification relate to array substrates and display devices which are capable of achieving high definition.

In the related art, as an example of a display device, liquid crystal display devices disclosed in JP 2016-4177 A, JP 2002-296610 A, and JP 2004-341330 A are known. The liquid crystal display device disclosed in JP 2016-4177 A includes a display region in which a plurality of pixels are disposed in a matrix having rows and columns, and the display region including a first configuration column in which first pixels including pixel electrodes each having a first region in which a plurality of electrodes extending in a first direction oblique to a column direction are disposed and a second region in which a plurality of electrodes extending in a second direction oblique to the first direction are disposed are arranged, and a second configuration column in which second pixels including pixel electrodes including a plurality of electrodes extending in a third direction oblique to the column direction and third pixels including pixel electrodes including a plurality of electrodes extending in an oblique fourth direction different from the third direction are alternately arranged.

In the liquid crystal display device disclosed in JP 2002-296610 A, a liquid crystal layer is sandwiched between a pair of substrates facing each other, and either a plurality of data signal lines or scanning signal lines of the liquid crystal display device having pixel electrodes connected to the data signal lines and the scanning signal lines arranged in parallel in a matrix on at least one substrate via switching elements are bent in one direction, and in the manufacturing method thereof, a treatment liquid for cleaning, etching, or the like is ejected in the same direction as the one direction.

The liquid crystal display device disclosed in JP 2004-341330 A includes a picture element electrode provided for each of a plurality of picture element regions on a liquid crystal layer side of a first substrate, a counter electrode provided on a second substrate and facing the picture element electrode with the liquid crystal layer interposed therebetween, a switching element electrically connected to the picture element electrode, and a scanning wiring line and a signal wiring line, at least one of which is provided on the first substrate. In each picture element region, the picture element electrode has a solid portion including a plurality of unit solid portions, and the liquid crystal layer forms a liquid crystal domain which is vertically aligned in a state where no voltage is applied and is radially inclined in a region corresponding to the unit solid portion by an oblique electric field generated around the unit solid portion in a state where a voltage is applied. The unit solid portion has four acute angle corner portions, and the four corner portions are directed to the upper side, the lower side, the right side, and the left side of a display surface, respectively. The scanning wiring line and the signal wiring line are inclined with respect to the vertical direction and the horizontal direction of the display surface and are bent a plurality of times in each picture element region.

### SUMMARY

The liquid crystal display device disclosed in JP 2016-4177 A is intended to improve a transmittance in a dual domain structure. The liquid crystal display device disclosed in JP 2002-296610 A is intended to prevent a residue of a liquid treatment solution such as water or an etching solution used in a manufacturing process from remaining. The liquid crystal display device disclosed in JP 2004-341330 A is intended to achieve a wide viewing angle characteristic and improve display characteristics. In the liquid crystal display devices disclosed in JP 2016-4177 A, JP 2002-296610 A, and JP 2004-341330 A, the scanning signal lines and the scanning wiring lines are formed in a bent shape in a plan view in order to achieve the respective objects, but none of them can achieve high definition.

The technique described in this specification has been made based on the circumstances described above, and an object thereof is to achieve high definition.

(1) An array substrate according to the technique described in this specification includes a semiconductor portion configured with a portion of a semiconductor film, a first insulating film disposed on an upper layer side of the semiconductor film, a first wiring line configured with a portion of a first conductive layer disposed on an upper layer side of the first insulating film, a second insulating film disposed on an upper layer side of the first conductive layer, and a first electrode configured with a portion of a second conductive layer disposed on an upper layer side of the second insulating film, in which the first electrode is disposed at a position spaced apart from the first wiring line in a first direction in such a manner that at least a portion of the first electrode overlaps a portion of the semiconductor portion,
a first contact hole connecting the semiconductor portion and the first electrode is provided at a position overlapping both the semiconductor portion and the first electrode in the first insulating film and the second insulating film, and the first wiring line includes a first bent portion that is bent to be recessed toward the first contact hole in a plan view so that a portion of the first wiring line overlaps the first contact hole in the first direction.

(2) In addition to (1) above, in the array substrate, the first wiring line may be configured such that a line segment connecting the first contact hole and the first wiring line at a shortest distance intersects the first bent portion and is inclined with respect to the first direction.

(3) In addition to (1) or (2) above, in the array substrate, the second insulating film may include a lower-layer-side second insulating film and an upper-layer-side second insulating film located on an upper layer side of the lower-layer-side second insulating film, the array substrate may include a second wiring line extending in the first direction, the second wiring line being configured with a portion of a third conductive layer disposed on a lower layer side of the upper-layer-side second insulating film on an upper layer side of the lower-layer-side second insulating film, the semiconductor portion may be disposed at a position spaced apart from the first wiring line in the first direction so that a portion of the semiconductor portion overlaps a portion of the second wiring line, a second contact hole connecting the semiconductor portion and the second wiring line may be provided at a position overlapping both the semiconductor portion and the second wiring line in the first insulating film and the lower-layer-side second insulating film, and the first wiring line may be configured to include a second bent portion that is bent to be recessed toward the second contact hole in a plan view so that a portion of the first wiring line overlaps the second contact hole in the first direction.

(4) In addition to (3) above, in the array substrate, the first wiring line may be configured such that a line segment connecting the second contact hole and the first wiring line at a shortest distance intersects the second bent portion and is inclined with respect to the first direction.

(5) In addition to (3) or (4) above, in the array substrate, the first bent portion and the second bent portion may have planar shapes symmetrical to each other.

(6) In addition to (5) above, the array substrate may further include a second electrode connected to the first electrode to configure a pixel which is a display unit, in which, when an angle formed by a line segment connecting the first contact hole and the first wiring line at a shortest distance with respect to the first direction is assumed to be “θ1”, a line width of the first wiring line is assumed to be “L”, a dimension of a range occupied by the first wiring line in the first direction in a plan view is assumed to be “W”, an arrangement interval of the pixels in the first direction is assumed to be “Py”, and an arrangement interval of the pixels in a second direction orthogonal to the first direction is assumed to be “Px”, the angle θ1 may satisfy a relationship “W=Px/2·tanθ1+L/cosθ1<Py/2”.

(7) In addition to any one of (1) to (6) above, the array substrate may further include a third insulating film disposed on an upper layer side of the second conductive layer, and a second electrode configured with a portion of a fourth conductive layer disposed on an upper layer side of the third insulating film and configuring a pixel which is a display unit, in which the first electrode may be disposed such that a portion of the first electrode overlaps at least a portion of the first bent portion, the second electrode may be disposed such that a portion of the second electrode overlaps both at least a portion of the first bent portion and a portion of the first electrode, and a third contact hole connecting the first electrode and the second electrode may be provided at a position overlapping both the first electrode and the second electrode in the third insulating film.

(8) In addition to any one of (1) to (7) above, the array substrate may further include a second electrode connected to the first electrode to configure a pixel which is a display unit, and a color filter disposed to overlap the second electrode.

(9) A display device according to the technique described in this specification includes the array substrate according to any one of (1) to (8) above, and a counter substrate facing the array substrate.

According to the technique described in this specification, it is possible to achieve high definition.

### BRIEF DESCRIPTION OF DRAWINGS

The disclosure will be described with reference to the accompanying drawings, wherein like numbers reference like elements.

FIG. 1 is a schematic plan view of a liquid crystal panel and a flexible substrate according to a first embodiment.

FIG. 2 is a schematic cross-sectional view of the liquid crystal panel according to the first embodiment.

FIG. 3 is a plan view illustrating a pixel array in a display region of an array substrate provided in the liquid crystal panel according to the first embodiment.

FIG. 4 is a cross-sectional view of the liquid crystal panel according to the first embodiment, taken along a line iv-iv in FIG. 3.

FIG. 5 is a cross-sectional view of the liquid crystal panel according to the first embodiment, taken along a line v-v in FIG. 3.

FIG. 6 is a cross-sectional view of the liquid crystal panel according to the first embodiment, taken along a line vi-vi in FIG. 3.

FIG. 7 is a plan view illustrating a relationship among a gate wiring line, a source wiring line, a semiconductor portion, a first contact hole, and a second contact hole in an array substrate according to the first embodiment.

FIG. 8 is a plan view illustrating a relationship among a range occupied by a gate wiring line in a Y-axis direction in a plan view, an arrangement interval in an X-axis direction in a pixel, a line width of the gate wiring line, and a first contact hole according to the first embodiment.

FIG. 9 is a graph showing a relationship between a value, which is obtained by dividing an arrangement interval in the Y-axis direction in a pixel by 2, and a dimension of a range occupied by a gate wiring line in the Y-axis direction in a plan view with respect to an angle formed by a first line segment and a second line segment with respect to the Y-axis direction according to the first embodiment.

FIG. 10 is a graph showing a relationship between an arrangement interval in the Y-axis direction in a pixel and a resolution with respect to an angle formed by the first line segment and the second line segment with respect to the Y-axis direction according to the first embodiment.

FIG. 11 is a plan view illustrating a pixel array in a display region of an array substrate according to a second embodiment.

FIG. 12 is a cross-sectional view of a liquid crystal panel according to the second embodiment, taken along a line xii-xii in FIG. 11.

FIG. 13 is a cross-sectional view of the liquid crystal panel according to the second embodiment, taken along a line xiii-xxiii in FIG. 11.

FIG. 14 is a cross-sectional view of the liquid crystal panel according to the second embodiment, taken along a line xiv-xiv in FIG. 11.

FIG. 15 is a plan view illustrating a relationship among a range occupied by a gate wiring line in the Y-axis direction in a plan view, an arrangement interval in the X-axis direction in a pixel, a line width of the gate wiring line, a line width of a source wiring line, and a first contact hole according to the second embodiment.

FIG. 16 is a graph showing a relationship between a value, which is obtained by dividing an arrangement interval in the Y-axis direction in a pixel by 2, and a dimension of a range occupied by a gate wiring line in the Y-axis direction in a plan view with respect to an angle formed by a first line segment and a second line segment with respect to the Y-axis direction according to the second embodiment.

FIG. 17 is a graph illustrating a relationship among an arrangement interval in the Y-axis direction in a pixel, an arrangement interval in the X-axis direction in the pixel, and a resolution with respect to an angle formed by the first line segment and the second line segment with respect to the Y-axis direction according to the second embodiment.

FIG. 18 is a plan view illustrating a pixel array in a display region of an array substrate according to a third embodiment.

FIG. 19 is a plan view illustrating a relationship among a range occupied by a gate wiring line in the Y-axis direction in a plan view, an arrangement interval in the X-axis direction in a pixel, a line width of the gate wiring line, a line width of a source wiring line, and a first contact hole according to the third embodiment.

FIG. 20 is a graph showing a relationship between a value, which is obtained by dividing an arrangement interval in the Y-axis direction in a pixel by 2, and a dimension of a range occupied by a gate wiring line in the Y-axis direction in a plan view with respect to an angle formed by a first line segment and a second line segment with respect to the Y-axis direction according to the third embodiment.

FIG. 21 is a graph illustrating a relationship among an arrangement interval in the Y-axis direction in a pixel, an arrangement interval in the X-axis direction in the pixel, and a resolution with respect to an angle formed by the first line segment and the second line segment with respect to the Y-axis direction according to the third embodiment.

### DESCRIPTION OF EMBODIMENTS

### First Embodiment

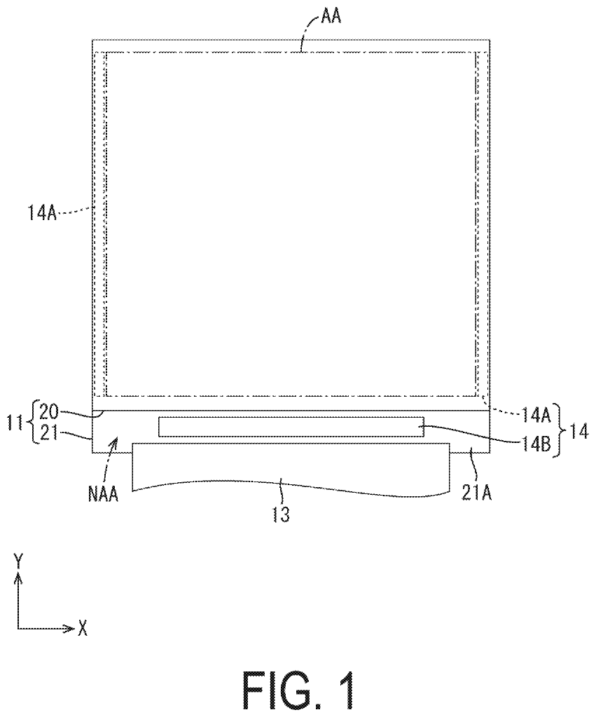

A first embodiment will be described with reference to FIG. 1 to FIG. 10. In the present embodiment, a liquid crystal display device (display device) 10 is exemplified. Some drawings illustrate an X-axis, a Y-axis, and a Z-axis, and directions of these axes are drawn to be common in all the drawings.

As illustrated in FIG. 1, the liquid crystal display device 10 includes a liquid crystal panel 11 and a backlight device (not shown) having a known configuration. A center-side portion of a screen of the liquid crystal panel 11 is a display region AA in which an image is displayed. A frame-shaped outer peripheral portion surrounding the display region AA of the screen of the liquid crystal panel 11 is a non-display region NAA in which no image is displayed. A range surrounded by a dot-dash line in FIG. 1 is the display region AA.

As illustrated in FIG. 1, the liquid crystal panel 11 is formed by bonding a pair of substrates 20 and 21 together. Out of the pair of substrates 20 and 21, one disposed on a front side is a counter substrate 20, and the other one disposed on a back side is an array substrate (active matrix substrate) 21. Both the counter substrate 20 and the array substrate 21 are formed by stacking various films on inner face sides of glass substrates 20GS and 21GS. Among these, a portion of the array substrate 21 protrudes laterally from the counter substrate 20, and a flexible substrate 13 for transmitting a signal from a control substrate is mounted on a protruding portion 21A.

As illustrated in FIG. 1, a circuit portion (peripheral circuit portion) 14 is provided in the non-display region NAA of the liquid crystal panel 11. The circuit portion 14 includes a first circuit portion 14A and a second circuit portion 14B. The first circuit portion 14A is a gate driver monolithic (GDM) circuit for supplying a scanning signal to a gate wiring line 25 to be described later. The scanning signal includes a potential (high potential) higher than a threshold voltage of a TFT 27 to be described later. The second circuit portion 14B is a source shared driving (SSD) circuit for supplying an image signal (data signal) to a source wiring line 26 to be described later.

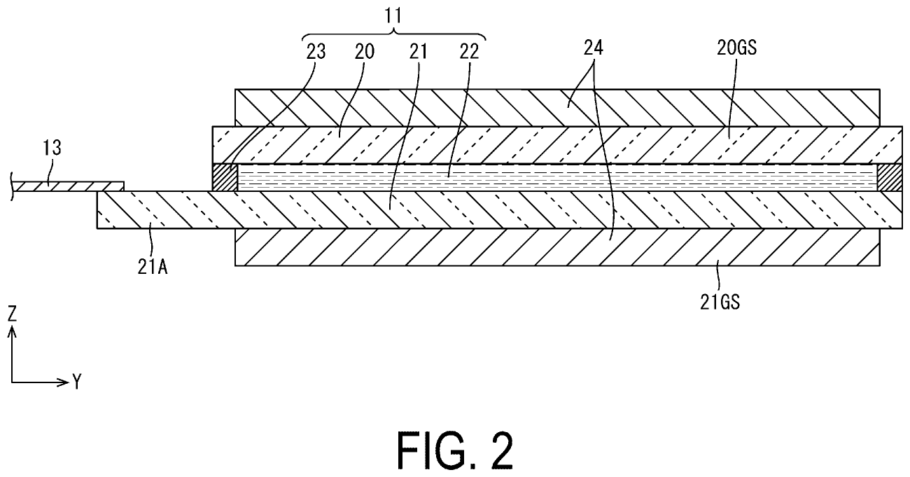

As illustrated in FIG. 2, the pair of substrates 20 and 21 are disposed to face each other at an interval in the Z-axis direction that is the normal direction of main surfaces of the substrates 20 and 21. At least a liquid crystal layer 22 and a sealing portion 23 sealing the liquid crystal layer 22 are interposed between the pair of substrates 20 and 21. The liquid crystal layer 22 contains liquid crystal molecules that serve as a material having optical characteristics changing in accordance with the application of an electrical field. The sealing portion 23 surrounds the liquid crystal layer 22 over the entire periphery. A polarizing plate 24 is attached to each of the outer surfaces of the pair of substrates 20 and 21.

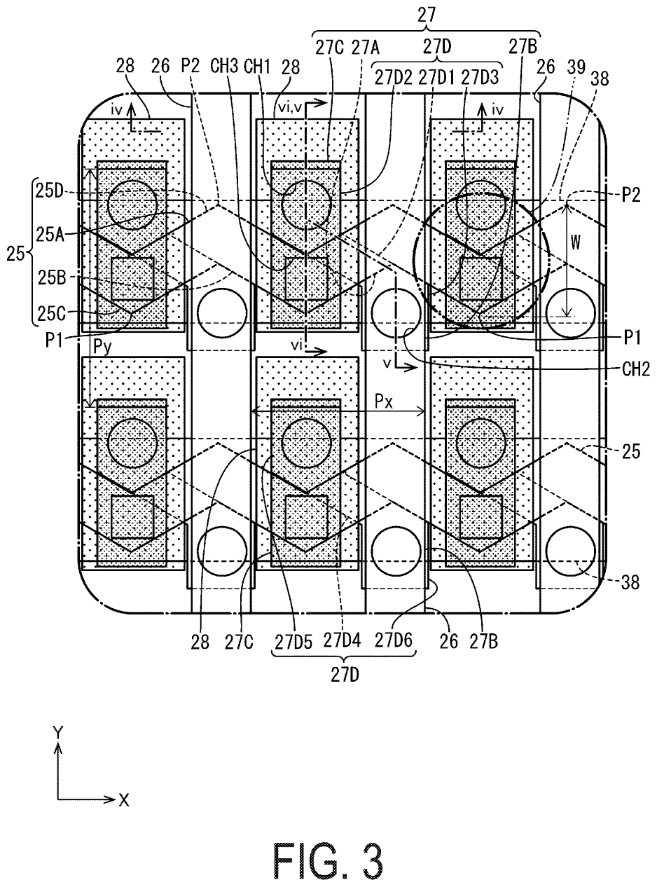

A pixel array in the display region AA of the array substrate 21 will now be described with reference to FIG. 3. A plurality of gate wiring lines (first wiring line, scanning wiring line) 25 and a plurality of source wiring lines (second wiring line, image wiring line, data wiring line) 26 each having a lattice shape are disposed on the inner face side of the display region AA of the array substrate 21 as illustrated in FIG. 3. Each of the gate wiring lines 25 extends substantially in the X-axis direction to cross the display region AA. The plurality of gate wiring lines 25 are disposed side by side at intervals in the Y-axis direction. A detailed configuration of the gate wiring line 25 will be described later. Scanning signals output from the first circuit portion 14A described above are supplied to the plurality of gate wiring lines 25 in a predetermined order (for example, from the upper stage side in FIG. 3). Each of the source wiring lines 26 extends in the Y-axis direction to cross the display region AA, and intersects the plurality of gate wiring lines 25. The plurality of source wiring lines 26 are disposed at intervals in the X-axis direction. Image signals output from the second circuit portion 14B described above are distributed to the source wiring lines 26.

As illustrated in FIG. 3, a TFT (thin film transistor, switching element) 27 is provided near an intersection between the gate wiring line 25 and the source wiring line 26. The TFT 27 is connected to the gate wiring line 25 and the source wiring line 26, as well as to a pixel electrode (second electrode) 28. The pixel electrode 28 is disposed between two source wiring lines 26 lined up at an interval in the X-axis direction. The pixel electrodes 28 have a longitudinal shape with the Y-axis direction as a longitudinal direction, and are disposed side by side in a matrix shape at intervals in the X-axis direction and the Y-axis direction. The TFT 27 includes a gate electrode 27A to which the gate wiring line 25 is connected, a source electrode 27B to which the source wiring line 26 is connected, a drain electrode (first electrode) 27C to which the pixel electrode 28 is connected, and a semiconductor portion 27D connected to the source electrode 27B and the drain electrode 27C. The TFT 27 is driven based on a high potential of a scanning signal supplied from the gate wiring line 25 to the gate electrode 27A. Then, a channel region is generated in the semiconductor portion 27D, and thus an image signal supplied from the source wiring line 26 to the source electrode 27B is supplied to the drain electrode 27C via the channel region. Thereby, the pixel electrode 28 is charged to a potential based on the image signal.

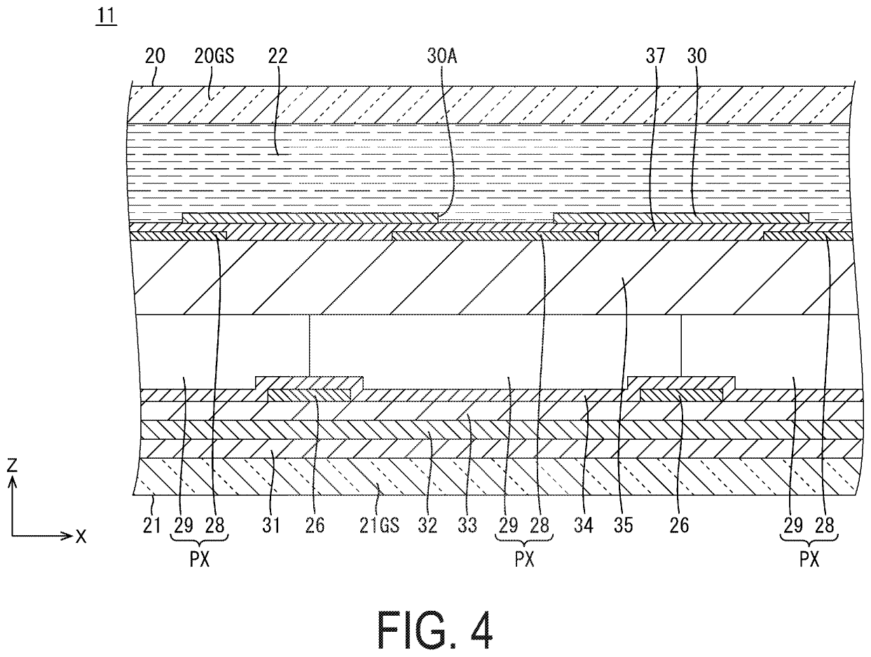

A color filter 29 is provided in addition to the pixel electrode 28 on the inner face side of the display region AA of the array substrate 21, as illustrated in FIG. 4. That is, the liquid crystal panel 11 according to the present embodiment can be regarded as having a color filter on array (COA) structure. The color filter 29 is disposed to overlap the pixel electrode 28 and configures a pixel PX, which is a display unit, together with the overlapping pixel electrode 28. The color filter 29 includes a plurality of types exhibiting colors different from each other. The color filters 29 may include, for example, three colors: a green color filter that exhibits green, a blue color filter that exhibits blue, and a red color filter that exhibits red. A plurality of types of color filters 29 that exhibit different colors may be arranged in a stripe pattern, or in a pen tile pattern. When the plurality of types of color filters 29 that exhibit different colors are arranged in a stripe pattern, their boundaries (color boundaries) overlap the source wiring line 26. When the plurality of types of color filters 29 that exhibit different colors are arranged in a pen tile pattern, their boundaries overlap the gate wiring line 25 and the source wiring line 26, respectively. The color filters 29 configure pixels PX that exhibit respective colors together with the overlapping pixel electrode 28, and the pixels PX of the respective colors configure a display pixel that can display a predetermined gradation color.

A common electrode 30 is provided on the inner face side of the display region AA of the array substrate 21, as illustrated in FIG. 4. The common electrode 30 is located on the upper layer side of the pixel electrode 28, and is disposed over substantially the entire display region AA. Thereby, the common electrode 30 overlaps all the pixel electrode 28 disposed in the display region AA. A plurality of slits 30A are formed to be open in respective portions overlapping the plurality of pixel electrodes 28 in the common electrode 30. A common potential signal serving as a common potential (reference potential) is supplied to the common electrode 30 via a common wiring line or the like (not shown). When the pixel electrode 28 is charged to a potential based on the image signal transmitted to the source wiring line 26 according to driving of the TFT 27, a potential difference is generated between the pixel electrode 28 and the common electrode 30. Then, a fringe electrical field (oblique electrical field) including a component in a normal direction with respect to a main surface of the array substrate 21 in addition to a component along the main surface of the array substrate 21 is generated between an opening edge of the slit 30A in the common electrode 30 and the pixel electrode 28. Thus, it is possible to control the alignment state of the liquid crystal molecules included in the liquid crystal layer 22 by using this fringe electrical field, and a predetermined display is performed based on the alignment state of the liquid crystal molecules. That is, an operation mode of the liquid crystal panel 11 according to the present embodiment is a fringe field switching (FFS) mode. An alignment film (not shown) for aligning the liquid crystal molecules contained in the liquid crystal layer 22 is provided on the innermost surface of each of the counter substrate 20 and the array substrate 21.

Subsequently, the various films stacked on the glass substrate 21GS of the array substrate 21 will be described in detail with reference to FIGS. 4 to 6. As illustrated in FIGS. 4 to 6, on the glass substrate 21GS of the array substrate 21, at least the following layers are stacked in order from the lower layer side (glass substrate 21GS side): a first metal layer, a first interlayer insulating film 31, a semiconductor film, a gate insulating film (first insulating film) 32, a second metal layer (first conductive layer), a second interlayer insulating film (second insulating film, lower-layer-side second insulating film) 33, a third metal layer (third conductive layer), a third interlayer insulating film (second insulating film, upper-layer-side second insulating film) 34, a first transparent electrode film (second conductive layer), a color filter 29, a first flattening film (third insulating film) 35, a second transparent electrode film (fourth conductive layer), a second flattening film 36, a fourth interlayer insulating film 37, a third transparent electrode film, and an alignment film.

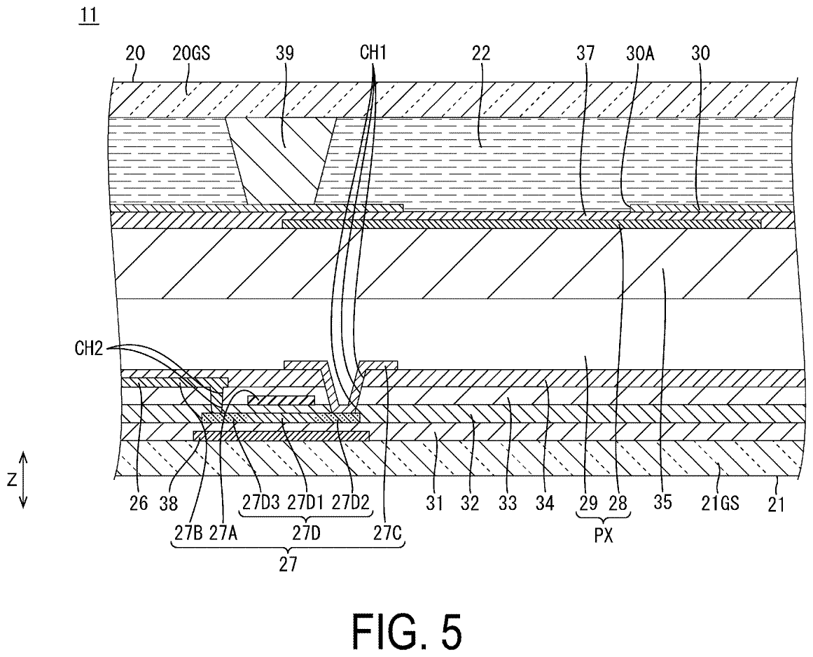

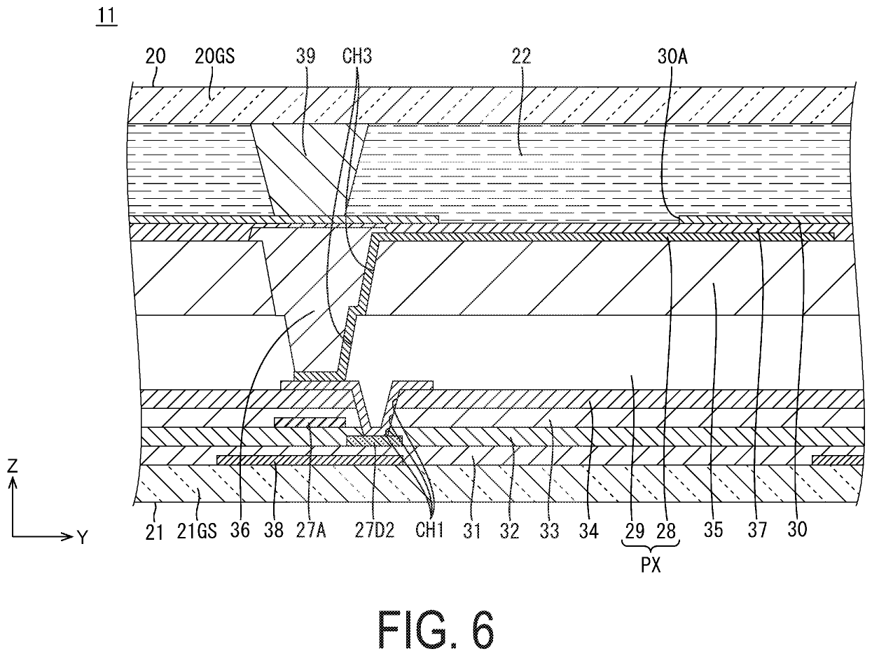

Each of the first metal layer, the second metal layer, and the third metal layer is a single-layer film made of one type of metal material or a layered film or alloy made of different types of metal materials, and thus has conductivity and light shielding properties. The first metal layer is a single-layer film made of, for example, W (tungsten) and has a film thickness of, for example, approximately 50 nm. The first metal layer configures a first light-shielding portion 38. As illustrated in FIGS. 5 and 6, the first light-shielding portion 38 is disposed at a position overlapping the semiconductor portion 27D of the TFT 27, and thus it is possible to shield light from the backlight device toward the semiconductor portion 27D. Thereby, it is possible to curb a variation in the characteristics of the TFT 27 which may occur when the semiconductor portion 27D is irradiated with light. The second metal layer may be, for example, a layered film of Ti (titanium)/Al (aluminum)/Ti stacked in that order from the lower layer side and respectively having film thicknesses of approximately 100 nm/150 nm/30 nm. The second metal layer configures the gate wiring line 25 and the gate electrode 27A. The third metal layer may be, for example, a layered film of Ti/Al/Ti stacked in that order from the lower layer side and respectively having film thicknesses of approximately 60 nm/300 nm/20 nm. The third metal layer configures the source wiring line 26 and the source electrode 27B.

The first transparent electrode film, the second transparent electrode film, and the third transparent electrode film are made of a transparent electrode material. The first transparent electrode film is made of, for example, indium zinc oxide (IZO) and has a film thickness of, for example, approximately 100 nm. As illustrated in FIGS. 5 and 6, the first transparent electrode film configures the drain electrode 27C. The second transparent electrode film is made of, for example, IZO and has a film thickness of, for example, approximately 100 nm. The second transparent electrode film configures the pixel electrode 28. The third transparent electrode film is made of, for example, IZO and has a film thickness of, for example, approximately 100 nm. The third transparent electrode film configures the common electrode 30.

The semiconductor film is made of, for example, an oxide semiconductor material and has a film thickness of, for example, approximately 50 nm. In detail, the semiconductor film includes, for example, an oxide thin film containing indium (In), gallium (Ga), and zinc (Zn) being a kind of oxide semiconductor. The oxide thin film containing indium (In), gallium (Ga), and zinc (Zn) is amorphous or crystalline. The oxide semiconductor material of the semiconductor film has characteristics of higher resistance value in a state in which no voltage is applied (off state) than the silicon semiconductor material. Further, the oxide semiconductor material of the semiconductor film has higher electron mobility than that of an amorphous silicon semiconductor material.

In the present embodiment, the semiconductor portion 27D made of a semiconductor film is configured with a non-low-resistance region 27D1 and low-resistance regions 27D2 and 27D3. In FIGS. 5 and 6, the low-resistance regions 27D2 and 27D3 of the semiconductor portion 27D are shown shaded. The non-low-resistance region 27D1 of the semiconductor portion 27D allows charge movement only under specific conditions (when a high potential of a scanning signal is supplied to the gate electrode 27A). The non-low-resistance region 27D1 overlaps the gate electrode 27A (a structure made of the second metal layer) in a plan view. The low-resistance regions 27D2 and 27D3 of the semiconductor portion 27D have an extremely low resistivity, for example, 1/10000000000 to 1/100, compared to the non-low-resistance region 27D1, thereby allowing charge movement at all times and functioning as a conductor. The low-resistance regions 27D2 and 27D3 do not overlap the gate electrodes 27A in a plan view. The low-resistance regions 27D2 and 27D3 include a first low-resistance region (drain region) 27D2 connected to the drain electrode 27C and a second low-resistance region (source region) 27D3 connected to the source electrodes 27B. The semiconductor portion 27D configured in this manner may be provided, for example, by performing a resistance reduction process during a manufacturing process. The resistance reduction process for the semiconductor portion 27D is performed using the gate electrode 27A as a mask after providing the gate wiring line 25 and the gate electrode 27A made of the second metal layer during the manufacturing process of the array substrate 21. The resistance reduction process is selectively performed on a portion (non-overlapping portion, exposed portion) of the semiconductor portion 27D which is not covered by the gate electrode 27A, and the resistance reduction process is not performed on a portion (overlapping portion, non-exposed portion) that is covered by the gate electrode 27A. The resistance reduction process includes, for example, a plasma process or an annealing process using a gas such as NH₃, H₂, N₂, or He. In addition to the resistance reduction process, the resistance of the semiconductor portion 27D may be selectively reduced, for example, by introducing hydrogen contained in the insulating films 31 to 37 into the portion not covered by the gate electrode 27A over time.

The first interlayer insulating film 31, the gate insulating film 32, the second interlayer insulating film 33, the third interlayer insulating film 34, and the fourth interlayer insulating film 37 are all made of an inorganic material (inorganic resin material). The first interlayer insulating film 31 may be a layered film of, for example, SiO₂ (silicon oxide)/SiNₓ (silicon nitride) stacked in that order from the lower layer side and respectively having film thicknesses of approximately 100 nm/150 nm. The first interlayer insulating film 31 is interposed between the first light-shielding portion 38 (first metal layer) and the gate wiring line 25 and gate electrode 27A (second metal layer) to keep them insulated. The gate insulating film 32 is made of SiO₂ and has a film thickness of, for example, approximately 85 nm. The gate insulating film 32 is interposed between the semiconductor portion 27D (semiconductor film) and the gate wiring line 25 and gate electrode 27A (second metal layer) to keep them insulated. The second interlayer insulating film 33 is made of, for example, SiO₂ and has a film thickness of, for example, approximately 500 nm. The second interlayer insulating film 33 is interposed between the gate wiring line 25 and gate electrode 27A (second metal layer) and the source wiring line 26 and source electrode 27B (third metal layer) to keep them insulated. The third interlayer insulating film 34 is made of, for example, SiO₂ and has a film thickness of, for example, approximately 500 nm. The third interlayer insulating film 34 is interposed between the source wiring line 26 (third metal layer) and the drain electrode 27C (first transparent electrode film) to keep them insulated. The fourth interlayer insulating film 37 is made of, for example, SiO₂ and has a film thickness of, for example, approximately 100 nm. The fourth interlayer insulating film 37 is interposed between the pixel electrode 28 (second transparent electrode film) and the common electrode 30 (third transparent electrode film) to keep them insulated.

As illustrated in FIG. 5, a first contact hole CH1 is provided at a position overlapping both the semiconductor portion 27D and the drain electrode 27C so as to communicate therewith in the gate insulating film 32, the second interlayer insulating film 33, and the third interlayer insulating film 34. The semiconductor portion 27D and the drain electrode 27C are connected to each other through the first contact hole CH1. A second contact hole CH2 is provided at a position overlapping both the semiconductor portion 27D and the source electrode 27B, which is a portion of the source wiring line 26, so as to communicate therewith in the gate insulating film 32 and the second interlayer insulating film 33. The semiconductor portion 27D and the source electrode 27B are connected to each other through the second contact hole CH2.

The first flattening film 35 and the second flattening film 36 are both made of an organic material (organic resin material). The first flattening film 35 and the second flattening film 36, which are made of an organic material, have film thicknesses larger than those of the first interlayer insulating film 31, the gate insulating film 32, the second interlayer insulating film 33, the third interlayer insulating film 34, and the fourth interlayer insulating film 37, which are made of an inorganic material. The first flattening film 35 is made of a photosensitive resin material (such as PMMA (acrylic resin)) and has a film thickness of, for example, approximately 1000 nm. The first flattening film 35, together with the color filter 29 to be described below, is interposed between the drain electrode 27C and the pixel electrode 28 to keep them insulated. The color filter 29 is made of color resist and is made by blending color materials (pigments or dyes) with a photosensitive resin material. The color filter 29 has a film thickness of, for example, approximately 1000 nm which is substantially the same as that of the first flattening film 35. As illustrated in FIG. 6, a third contact hole CH3 is opened in a portion overlapping both the drain electrode 27C and the pixel electrode 28 in the first flattening film 35 and the color filter 29. The drain electrode 27C and the pixel electrode 28 are connected to each other through the third contact hole CH3. The second flattening film 36 is made of a photosensitive resin material (such as PMMA) and has a film thickness of, for example, approximately 1000 nm which is substantially the same as that of the first flattening film 35. The second flattening film 36 is provided at a position overlapping the third contact hole CH3. That is, the third contact hole CH3 is filled with the second flattening film 36, thereby flattening the pixel electrode 28 and the common electrode 30 that are located on the upper layer side of the second flattening film 36.

On the other hand, as illustrated in FIGS. 5 and 6, a spacer 39 and an alignment film are formed on the glass substrate 20GS of the counter substrate 20. The spacers 39 protrude from the counter substrate 20 toward the array substrate 21 in the Z-axis direction (the normal direction of the main surface of the counter substrate 20) and have a protruding tip surface facing the array substrate 21. The spacer 39 has a slightly tapered cylindrical shape as a whole. The spacer 39 can maintain an interval (the thickness of the liquid crystal layer 22, a cell gap) between the pair of substrates 20 and 21 by having the protruding tip surface in contact with the inner surface of the array substrate 21 via the alignment film.

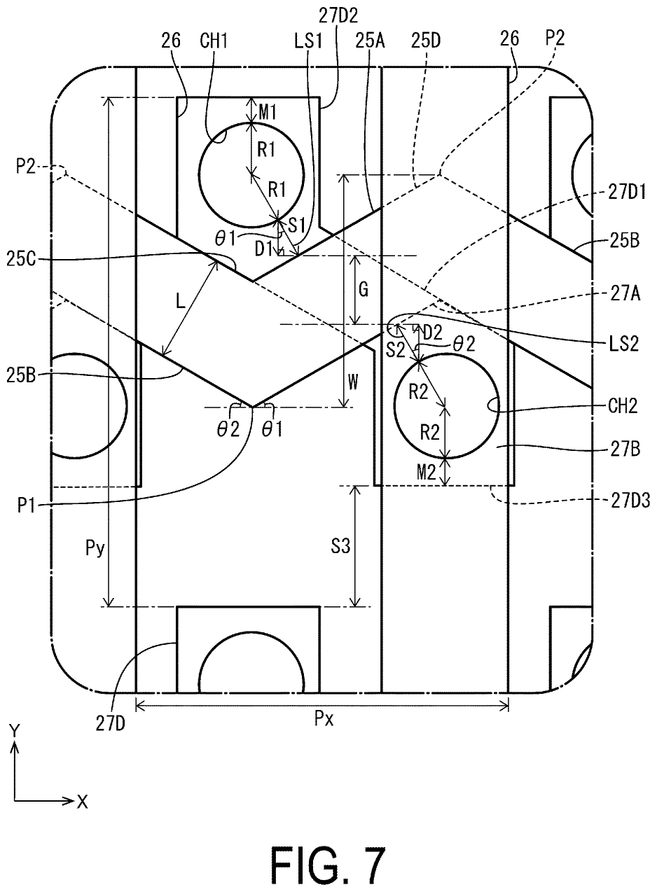

Next, a detailed planar configuration of each structure provided on the array substrate 21 will be described mainly with reference to FIGS. 3 and 7. As illustrated in FIG. 3, the first light-shielding portion 38 has a horizontally elongated band shape extending in the X-axis direction in a plan view, and is disposed to overlap the entire region of the gate wiring line 25 in a plan view. The width dimension of the first light-shielding portion 38 is greater than the range occupied by the gate wiring line 25 in the Y-axis direction. Thus, it can be said that the first light-shielding portion 38 covers, from the back side, the entire region of the non-low-resistance region 27D1 (including a channel region) of the semiconductor portion 27D, which overlaps the gate electrode 27A configured with a portion of the gate wiring line 25. Thereby, it is possible to effectively shield light from the backlight device toward the non-low-resistance region 27D1 of the semiconductor portion 27D by the first light-shielding portion 38.

As illustrated in FIG. 3, the drain electrode 27C and the pixel electrode 28 both have a vertically elongated rectangular shape extending in the Y-axis direction in a plan view. The pixel electrode 28 has a short side dimension (dimension in the X-axis direction) and a long side dimension (dimension in the Y-axis direction) that are larger than those of the drain electrode 27C. The ratio of the short side dimension to the long side dimension of the pixel electrode 28 is, for example, 3:4. The short side dimension of the pixel electrode 28 matches an arrangement interval (arrangement pitch) Px between the pixels PX in the X-axis direction, and the long side dimension of the pixel electrode 28 matches an arrangement interval Py between the pixels PX in the Y-axis direction. The pixel electrode 28 is configured such that one end overlaps one (lower side in FIG. 3) of two gate wiring lines 25 sandwiching the pixel electrode 28 in the Y-axis direction, and the other end is disposed spaced from the other gate wiring line 25 (upper side in FIG. 3) in the Y-axis direction.

As illustrated in FIG. 3, the entire region of the drain electrode 27C overlaps the pixel electrode 28 and is disposed to be biased toward one end (lower side in FIG. 3) of the pixel electrode 28. One end (lower side in FIG. 3) of the drain electrode 27C overlaps one end of the pixel electrode 28 and the gate wiring line 25, while the other end (upper side in FIG. 3) overlaps the other end (first low-resistance region 27D2) of the semiconductor portion 27D to be described below. The drain electrode 27C is disposed at a position spaced apart from the gate wiring line 25 in the Y-axis direction in such a manner that a portion of the drain electrode 27C overlaps a portion of the semiconductor portion 27D. The overlapping ends of the pixel electrode 28 and the drain electrode 27C are connected to each other through the third contact hole CH3 provided in the color filter 29 and the first flattening film 35, as illustrated in FIG. 6. As illustrated in FIG. 3, the third contact hole CH3 is disposed such that its center matches the center position of the pixel PX in the X-axis direction. The third contact hole CH3 is disposed at a position spaced apart from the first contact hole CH1 on the lower side in FIG. 3. The third contact hole CH3 has a substantially rectangular planar shape. The overlapping ends (third contact hole CH3) of the pixel electrode 28 and the drain electrode 27C are disposed to overlap not only the gate wiring line 25, but also parts of the first light-shielding portion 38 and the semiconductor portion 27D. Furthermore, the spacer 39 of the counter substrate 20 overlaps the third contact hole CH3.

As illustrated in FIG. 7, the semiconductor portion 27D has a first extending portion (first oblique extending portion) 27D4 that extends in an oblique direction inclined with respect to both the X-axis and Y-axis directions. The first extending portion 27D4 of the semiconductor portion 27D is disposed to cross the gate wiring line 25 to be described later, and includes the entire region of the non-low-resistance region 27D1 and parts of the first low-resistance region 27D2 and the second low-resistance region 27D3 (parts adjacent to the non-low-resistance region 27D1). The portion of the gate wiring line 25 which overlaps the first extending portion 27D4 configures the gate electrode 27A. More specifically, the first extending portion 27D4 extends in an obliquely downward right direction (obliquely upward left direction) in FIG. 3 so as to be away from the drain electrode 27C to be connected and to approach the source electrode 27B (source wiring line 26) to be connected. In the first extending portion 27D4, a portion located on the drain electrode 27C side (upper side in FIG. 3) with respect to the gate wiring line 25 in the Y-axis direction configures a portion of the first low-resistance region 27D2, and a portion located on the source electrode 27B side (lower side in FIG. 3) with respect to the gate wiring line 25 in the Y-axis direction configures a portion of the second low-resistance region 27D3. The non-low-resistance region 27D1 and the first low-resistance region 27D2, which are parts of the first extending portion 27D4, partially overlap the drain electrode 27C and the pixel electrode 28, and the non-low-resistance region 27D1 and the second low-resistance region 27D3, which are parts of the first extending portion 27D4, partially overlap the source wiring line 26.

As illustrated in FIG. 7, the semiconductor portion 27D has a pair of straight portions 27D5 and 27D6 that are connected to both ends of the first extending portion 27D4 and extend substantially straight in the Y-axis direction. One straight portion 27D5 out of the pair of straight portions 27D5 and 27D6 overlaps the drain electrode 27C and configures a portion of the first low-resistance region 27D2. The other straight portion 27D6 out of the pair of straight portions 27D5 and 27D6 overlaps a portion of the source wiring line 26 and configures a portion of the second low-resistance region 27D3. A portion of the source wiring line 26 which overlaps the other straight portion 27D6 configures the source electrode 27B. As illustrated in FIG. 5, one straight portion 27D5 (first low-resistance region 27D2) and the drain electrode 27C are connected to each other through the first contact hole CH1 provided in the gate insulating film 32, the second interlayer insulating film 33, and the third interlayer insulating film 34. The other straight portion 27D6 (second low-resistance region 27D3) and the source electrode 27B are connected to each other through the second contact hole CH2 provided in the gate insulating film 32 and the second interlayer insulating film 33.

As illustrated in FIG. 7, the first contact hole CH1 is disposed such that its center matches the center position of the pixel PX in the X-axis direction, and its center is located on the same straight line as the center of the third contact hole CH3 in the Y-axis direction. The first contact hole CH1 is disposed at a position spaced apart from the gate wiring line 25 in the Y-axis direction, thereby preventing a short circuit between the gate wiring line 25 and the drain electrode 27C through the first contact hole CH1. The first contact hole CH1 has a substantially circular planar shape. The second contact hole CH2 is disposed so that its center matches the center position of the source wiring line 26 in the X-axis direction. The second contact hole CH2 is disposed at a position spaced apart from the first contact hole CH1 on the diagonally lower right side in FIG. 7. The second contact hole CH2 is disposed at a position spaced apart from the gate wiring line 25 in the Y-axis direction, thereby preventing a short circuit between the gate wiring line 25 and the source wiring line 26 through the second contact hole CH2. The second contact hole CH2 has a substantially circular planar shape.

Next, the planar configuration of the gate wiring line 25 will be described in detail. As illustrated in FIG. 3, the gate wiring line 25 extends substantially in the X-axis direction as a whole, but is repeatedly bent in a zigzag shape in a plan view. The gate wiring line 25 includes a second extending portion (second diagonal extending portion) 25A extending in an oblique direction inclined with respect to both the X-axis and Y-axis directions, and a third extending portion (third diagonal extending portion) 25B extending in an oblique direction different from that of the second extending portion 25A. The second extending portion 25A extends in an obliquely upward right direction (obliquely downward left direction) in FIG. 3 and intersects with the first extending portion 27D4 of the semiconductor portion 27D. Thus, the second extending portion 25A includes the gate electrode 27A, which is a portion overlapping the non-low-resistance region 27D1 of the semiconductor portion 27D in a plan view. The second extending portion 25A is inclined at a predetermined angle with respect to the X-axis direction. The third extending portion 25B extends in an obliquely downward right direction (obliquely upward left direction) in FIG. 3 and is parallel to the first extending portion 27D4 of the semiconductor portion 27D. The third extending portion 25B is inclined at a predetermined angle with respect to the X-axis direction. In the present embodiment, the angle formed by the second extending portion 25A with respect to the X-axis direction is the same as the angle formed by the third extending portion 25B with respect to the X-axis direction. Furthermore, the angle formed by the third extending portion 25B with respect to the X-axis direction is the same as the angle formed by the first extending portion 27D4 of the semiconductor portion 27D with respect to the X-axis direction. In other words, the third extending portion 25B is parallel to the first extending portion 27D4.

As illustrated in FIG. 3, the gate wiring line 25 is configured by repeatedly connecting the second extending portions 25A and the third extending portions 25B configured as described above, resulting in a zigzag shape in a plan view as a whole. The gate wiring line 25 is bent at junctions between the second extending portions 25A and the third extending portions 25B. The junctions between the second extending portions 25A and the third extending portions 25B, that is, bent points of the gate wiring line 25, are located at the center position of the pixel PX in the X-axis direction and the center position of the source wiring line 26 in the X-axis direction. The zigzag-shaped gate wiring line 25 includes a plurality of first bent points P1 located at the center position of the pixel PX in the X-axis direction and a plurality of second bent points P2 located at the center position of the source wiring line 26 in the X-axis direction. The first bent point P1 is located at the lower end of the gate wiring line 25 in FIG. 3. The plurality of first bent points P1 included in one gate wiring line 25 are located on the same straight line in the X-axis direction. The number of first bent points P1 included in one gate wiring line 25 is equal to the number of pixels PX in one row (the number of pixels PX lined up in the X-axis direction). The second bent point P2 is located at the upper end of the gate wiring line 25 in FIG. 3. The plurality of second bent points P2 included in one gate wiring line 25 are located on the same straight line in the X-axis direction. The number of second bent points P2 included in one gate wiring line 25 is equal to the number of source wiring lines 26. A distance in the Y-axis direction between the first bent point P1 and the second bent point P2 is a range W occupied by the gate wiring line 25 in the Y-axis direction in a plan view.

As illustrated in FIG. 7, the gate wiring line 25 has a first bent portion 25C that includes a first bent point P1 located at the center position of the pixel PX in the X-axis direction. The first bent portion 25C is configured with portions of the second extending portion 25A and the third extending portion 25B which configure the first bent point P1. The first bent portion 25C is recessed upward in FIG. 3, that is, toward the first contact hole CH1, and is substantially V-shaped in a plan view. The first bent point P1 included in the first bent portion 25C is located on the same straight line as the center of the first contact hole CH1 in the Y-axis direction. The number of first bent portions 25C provided in one gate wiring line 25 is equal to the number of first bent points P1 (the number of pixels PX in one row). The gate wiring line 25 is configured such that a portion of the gate wiring line 25 overlaps the first contact hole CH1 in the Y-axis direction (first direction). In detail, the range occupied by the gate wiring line 25 in the Y-axis direction in a plan view (the range indicated by “W” in FIG. 7) includes a portion of the first contact hole CH1. More specifically, most of the first contact hole CH1, including its center, is included in the range (a triangular range in a plan view) defined by the gate wiring line 25 and a straight line in the X-axis direction (a second direction orthogonal to the first direction) connecting the plurality of second bent points P2. With such a configuration, the range occupied by the gate wiring line 25 and the first contact hole CH1 in the Y-axis direction in a plan view can be narrowed by the amount that the gate wiring line 25 and the first contact hole CH1 overlap in the Y-axis direction. Thereby, the arrangement interval Py between the pixels PX in the Y-axis direction can be reduced, which is advantageous for achieving high definition. Furthermore, a sufficient interval is ensured between the first contact hole CH1 and the gate wiring line 25.

As illustrated in FIG. 7, the gate wiring line 25 has a second bent portion 25D that includes a second bent point P2 located at the center position of the source wiring line 26 in the X-axis direction. The second bent portion 25D is configured with portions of the second extending portion 25A and the third extending portion 25B which configure the second bent point P2. The second bent portion 25D is recessed downward in FIG. 3, that is, toward the second contact hole CH2, and has a substantially inverted V-shape in a plan view. The second bent point P2 included in the second bent portion 25D is located on the same straight line as the center of the second contact hole CH2 in the Y-axis direction. The number of second bent portions 25D included in one gate wiring line 25 is equal to the number of second bent points P2 (the number of source wiring lines 26). The gate wiring line 25 is configured such that a portion of the gate wiring line 25 overlaps the second contact hole CH2 in the Y-axis direction. In detail, the range occupied by the gate wiring line 25 in the Y-axis direction in a plan view includes a portion of the second contact hole CH2. More specifically, most of the second contact hole CH2, including its center, is included in the range (a triangular range in a plan view) defined by the gate wiring line 25 and a straight line in the X-axis direction connecting the plurality of first bent points P1. With such a configuration, the range occupied by the gate wiring line 25 and the second contact hole CH2 in the Y-axis direction in a plan view can be narrowed by the amount that the gate wiring line 25 and the second contact hole CH2 overlap in the Y-axis direction. Thereby, the arrangement interval Py between the pixels PX in the Y-axis direction can be reduced, which is advantageous for achieving high definition. Furthermore, a sufficient interval is ensured between the second contact hole CH2 and the gate wiring line 25.

Here, as illustrated in FIG. 7, a line segment connecting the first contact hole CH1 and the gate wiring line 25 at the shortest distance is referred to as a “first line segment LS1.” The gate wiring line 25 has a zigzag shape in which the second extending portions 25A and the third extending portions 25B extending in an oblique direction with respect to the X-axis and Y-axis directions are alternately connected to each other. Thus, the first line segment LS1 connecting the first contact hole CH1 and the gate wiring line 25 at the shortest distance intersects the first bent portion 25C and is inclined with respect to the Y-axis direction. FIG. 7 illustrates the first line segment LS1 intersecting the first contact hole CH1 and the second extending portion 25A of the gate wiring line 25. The first line segment LS1 is perpendicular to the extension direction of the second extending portion 25A. Thus, an angle θ1 formed by the first line segment LS1 with respect to the Y-axis direction is equal to an angle formed by the second extending portion 25A with respect to the X-axis direction. When the length of the first line segment LS1 is “S1”, a distance in the Y-axis direction from an intersection between the first line segment LS1 and the first contact hole CH1 to an intersection between the first line segment LS1 and the gate wiring line 25 is “D1”, and an angle formed by the first line segment LS1 with respect to the Y-axis direction is “θ1”, “D1=S1·cosθ1” is established. A relationship in which the first line segment LS1 connecting the first contact hole CH1 and the gate wiring line 25 at the shortest distance intersects the first bent portion 25C and is inclined with respect to the first direction is expressed as “0°<θ1<90°”. When the θ1 is substituted into “D1=S1·cosθ1”, the relationship “D1<S1” is obtained. Thus, compared to a case where the first line segment LS1 is parallel to the Y-axis direction, that is, “θ1=0°” (“D1=S1”), the first contact hole CH1 can be disposed closer to the gate wiring line 25 in the Y-axis direction by the amount of “D1−S1”. Thereby, the range occupied by the gate wiring line 25 and the first contact hole CH1 in the Y-axis direction in a plan view can be narrowed, which is advantageous for achieving high definition.

As illustrated in FIG. 7, a line segment connecting the second contact hole CH2 and the gate wiring line 25 at the shortest distance is referred to as a “second line segment LS2”. The gate wiring line 25 has a zigzag shape in which the second extending portions 25A and the third extending portions 25B extending in an oblique direction with respect to the X-axis and Y-axis directions are alternately connected to each other. Thus, the second line segment LS2 connecting the second contact hole CH2 and the gate wiring line 25 at the shortest distance intersects the second bent portion 25D and is inclined with respect to the Y-axis direction. FIG. 7 illustrates the second line segment LS2 intersecting the second contact hole CH2 and the second extending portion 25A of the gate wiring line 25. The second line segment LS2 is perpendicular to the extension direction of the second extending portion 25A. Thus, an angle θ2 formed by the second line segment LS2 with respect to the Y-axis direction is equal to an angle formed by the second extending portion 25A with respect to the X-axis direction. When the length of the second line segment LS2 is “S2”, a distance in the Y-axis direction from an intersection between the second line segment LS2 and the second contact hole CH2 to an intersection between the second line segment LS2 and the gate wiring line 25 is “D2”, and an angle formed by the second line segment LS2 with respect to the Y-axis direction is “θ2”, “D2=S2·cosθ2” is established. A relationship in which the second line segment LS2 connecting the second contact hole CH2 and the gate wiring line 25 at the shortest distance intersects the second bent portion 25D and is inclined with respect to the Y-axis direction is expressed as “0°<θ2<90°”. When the θ2 is substituted into “D2=S2·cosθ2”, the relationship “D2<S2” is obtained. Thus, compared to a case where the second line segment LS2 is parallel to the Y-axis direction, that is, “θ2=0°” (“D2=S2”), the second contact hole CH2 can be disposed closer to the gate wiring line 25 in the Y-axis direction by the amount of “D2−S2”. Thereby, the range occupied by the gate wiring line 25 and the second contact hole CH2 in the Y-axis direction in a plan view can be narrowed, which is advantageous for achieving high definition.

As illustrated in FIG. 7, the first bent portion 25C and the second bent portion 25D included in the gate wiring line 25 have planar shapes that are symmetrical to each other. In detail, the first bent portion 25C, which is substantially V-shaped in a plan view, and the second bent portion 25D, which is substantially inverted V-shaped in a plan view, are line-symmetrically with respect to a symmetrical line which is a straight line in the X-axis direction. This facilitates the design of the gate wiring line 25. The angle θ1 formed by the first line segment LS1 connecting the first contact hole CH1 and the gate wiring line 25 at the shortest distance with respect to the Y-axis direction is equal to the angle θ2 formed by the second line segment LS2 connecting the second contact hole CH2 and the gate wiring line 25 at the shortest distance with respect to the Y-axis direction.

Next, with the configuration according to the present embodiment, it was verified how much the arrangement interval Py between the pixels PX in the Y-axis direction can be reduced. The radius of the first contact hole CH1 is assumed to be “R1”, the length of the first line segment LS1 is assumed to be “S1”, and the shortest distance between the first contact hole CH1 and the end of one straight portion 27D5 of the semiconductor portion 27D is assumed to be “M1”. The radius of the second contact hole CH2 is assumed to be “R2”, the length of the second line segment LS2 is assumed to be “S2”, and the shortest distance between the second contact hole CH2 and the end of the other straight portion 27D6 of the semiconductor portion 27D is assumed to be “M2”. An angle formed by the first line segment LS1 and the second line segment LS2 with respect to the Y-axis direction (an angle formed by the second extending portion 25A and the third extending portion 25B with respect to the X-axis direction) is assumed to be “θ”. The angle θ is equal to the angles θ1 and θ2 described prior to the present paragraph. A distance in the Y-axis direction between the end of the other straight portion 27D6 in the semiconductor portion 27D and the end of one straight portion 27D5 in the semiconductor portion 27D located on the lower stage side thereof is assumed to be “S3”. The line width of the gate wiring line 25 is assumed to be “L”. A distance in the Y-axis direction from an intersection between the first line segment LS1 and the gate wiring line 25 to an intersection between the second line segment LS2 and the gate wiring line 25 is assumed to be “G”.

The arrangement interval Py between the pixels PX in the Y-axis direction is expressed by the following equation “Py=M1+R1+(R1+S1)·cosθ+G+(R2+S2)·cosθ+M2+R2+S3”. Here, if the first line segment LS1 and the second line segment LS2 are parallel to the Y-axis direction, that is, when “θ=0°” (“cosθ=1”), the arrangement interval Py between the pixels PX in the Y-axis direction is expressed by the following equation “Py=M1+R1+(R1+S1)+L+(R2+S2)+M2+R2+S3”. The distance G is also expressed by the following equation “L·cosθ”. When the arrangement interval Py when “θ1=θ2=0°” is subtracted from the arrangement interval Py when “0°<θ1, θ2<90°”, the difference is expressed by the following equation “(R1+R2+S1+S2)·(cosθ−1)+L·(cosθ−1)”. Thus, according to the present embodiment, it can be said that the arrangement interval Py between the pixels PX in the Y-axis direction can be reduced by the amount of the difference described above, compared to when the gate wiring lines 25 extend linearly in the X-axis direction. Based on the equation of the difference described above, the greater the angle θ formed by the first line segment LS1 and the second line segment LS2 with respect to the Y-axis direction, the greater the reduction in the arrangement interval Py between the pixels PX in the Y-axis direction, which is advantageous for achieving high definition.

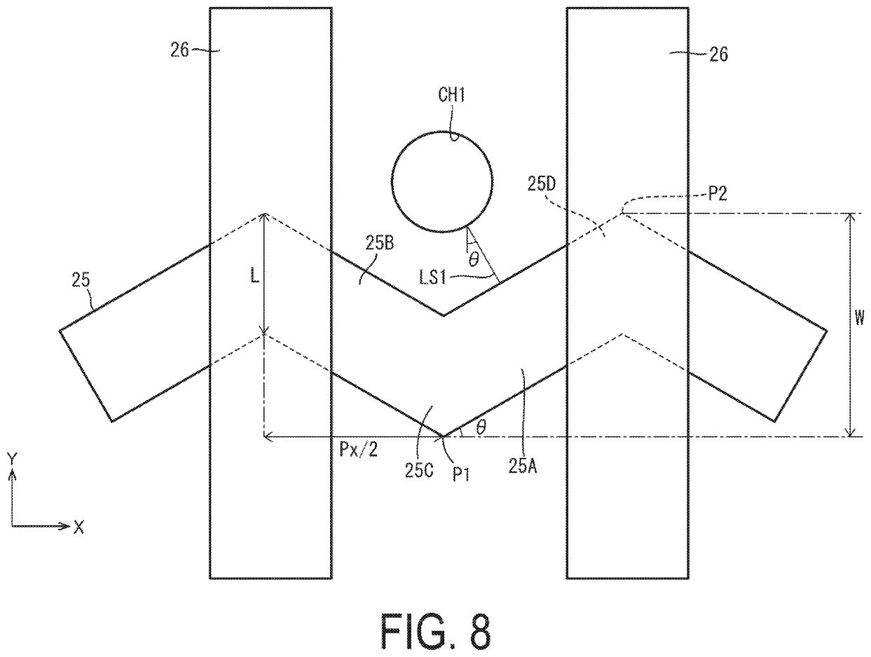

On the other hand, when the angle θ formed by the first line segment LS1 and the second line segment LS2 with respect to the Y-axis direction, that is, the angle formed by the second extending portion 25A and the third extending portion 25B with respect to the X-axis direction, is increased, the range occupied by the gate wiring lines 25 in the Y-axis direction in a plan view is expanded, as illustrated in FIG. 8. Since the gate wiring line 25 shields light from the backlight device on the array substrate 21, it can be said to be a structure that does not contribute to display. Thus, when the angle θ formed by the first line segment LS1 and the second line segment LS2 with respect to the Y-axis direction is made too large in order to reduce the arrangement interval Py between the pixels PX in the Y-axis direction, the range occupied by the gate wiring lines 25 in the Y-axis direction in a plan view becomes too wide, which may result in an excessive reduction in an aperture ratio of the pixel PX.

Consequently, in the present embodiment, an upper limit value of the angle θ formed by the first line segment LS1 and the second line segment LS2 with respect to the Y-axis direction is defined as follows. That is, when the angle formed by the first line segment LS1 and the second line segment LS2 with respect to the Y-axis direction is assumed to be “θ”, the line width of the gate wiring line 25 is assumed to be “L”, the dimension of the range occupied by the gate wiring lines 25 in the Y-axis direction in a plan view is assumed to be “W”, the arrangement interval between the pixels PX in the Y-axis direction is assumed to be “Py”, and the arrangement interval between the pixels PX in the X-axis direction is assumed to be “Px”, the angle θ formed by the first line segment LS1 and the second line segment LS2 with respect to the Y-axis direction satisfies a relationship “W=Px/2·tanθ+L/cosθ<Py/2”. The dimension W of the range occupied by the gate wiring lines 25 with respect to the Y-axis direction in a plan view can be expressed by the equation “W=Px/2·tanθ+L/cosθ”. By setting the angle θ so as to satisfy the relationship “W<Py/2”, the range occupied by the pixels PX, which are components that contribute to display, in the Y-axis direction in a plan view can be made at least twice the range occupied by the gate wiring lines 25, which do not contribute to display, in the Y-axis direction in a plan view. Thus, by setting the upper limit value of the angle θ so as to satisfy the above equation, the aperture ratio between the pixels PX can be kept sufficiently high, which is more preferable for achieving high definition.

Next, specific calculations were performed to determine how the arrangement interval Py between the pixels PX in the Y-axis direction and the dimension W of the range occupied by the gate wiring lines 25 in the Y-axis direction in a plan view change depending on the angle θ formed by the first line segment LS1 and the second line segment LS2 with respect to the Y-axis direction. The arrangement interval Py between the pixels PX in the Y-axis direction was calculated by substituting specific numerical values into the equation “Py=M1+R1+(R1+S1)·cosθ+G+(R2+S2)·cosθ+M2+R2+S3”. Similarly, the dimension W of the range occupied by the gate wiring lines 25 in the Y-axis direction in a plan view was calculated by substituting specific numerical values into the equation “W=Px/2·tanθ+L/cosθ”. Here, the numerical values of M1 and M2 are each set to 0.5 μm, the numerical values of R1 and R2 are each set to 0.9 μm, the numerical values of S1 and S2 are each set to 1 μm, the numerical value of S3 is set to 2 μm, and the numerical value of L is set to 1 μm. In the present embodiment, the ratio of the short side dimension to the long side dimension of the pixel electrode 28 is 3:4, and thus “Px=3·Py/4”. The numerical value of G can also be calculated based on “G=L·cosθ”.

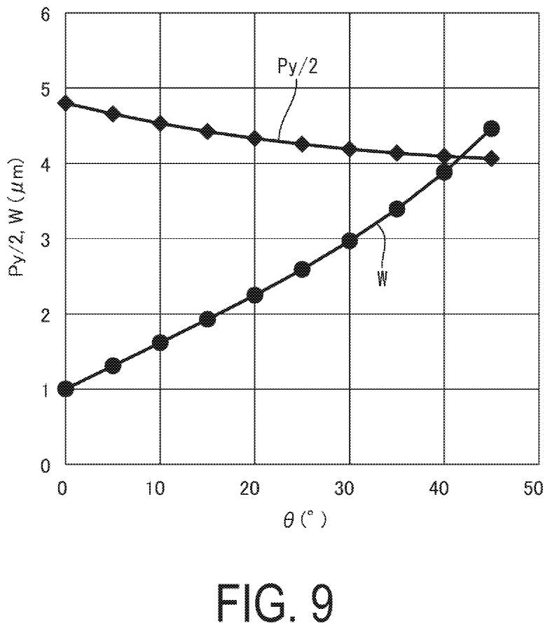

FIG. 9 shows calculation results of the arrangement interval Py between the pixels PX in the Y-axis direction and the dimension W of the range occupied by the gate wiring lines 25 in the Y-axis direction in a plan view. FIG. 9 is a graph in which the horizontal axis represents an angle θ (unit is “°”) formed by the first line segment LS1 and the second line segment LS2 with respect to the Y-axis direction, and the vertical axis represents a value obtained by dividing the arrangement interval Py between the pixels PX in the Y-axis direction by 2 (Py/2: unit is “μm”) and the dimension W (unit is “μm”) of the range occupied by the gate wiring lines 25 in the Y-axis direction in a plan view. According to FIG. 9, when “θ=0°”, the numerical value of Py/2 is approximately “4.8 μm”, and the numerical value of W is approximately “1 μm”. According to FIG. 9, it can be understood that as the value of θ increases from 0°, the numerical value of Py/2 tends to decrease and the numerical value of W tends to increase. In FIG. 9, an intersection between the calculation result of Py/2 and the calculation result of W indicates that “W=Py/2”. Thus, when θ is set to a value smaller than the intersection between the calculation result of Py/2 and the calculation result of W, the relationship “W=Px/2·tanθ+L/cosθ<Py/2” is satisfied. According to FIG. 9, it is preferable to set θ to 40° or less, and setting θ to approximately 40° is preferable for achieving both high definition and a high aperture ratio. Referring to the plot where θ is 40°, the numerical value of Py/2 is approximately “4.1 μm”, and the numerical value of W is approximately “3.9 μm”.

Next, specific calculations were performed to determine how the arrangement interval Py between the pixels PX in the Y-axis direction and a resolution change depending on the angle θ formed by the first line segment LS1 and the second line segment LS2 with respect to the Y-axis direction. The arrangement interval Py between the pixels PX in the Y-axis direction was calculated in the same manner as above. Regarding the resolution, the number of pixels per inch (ppi) was calculated based on the arrangement interval Py between the pixels PX in the Y-axis direction and the arrangement interval Px between the pixels PX in the X-axis direction.

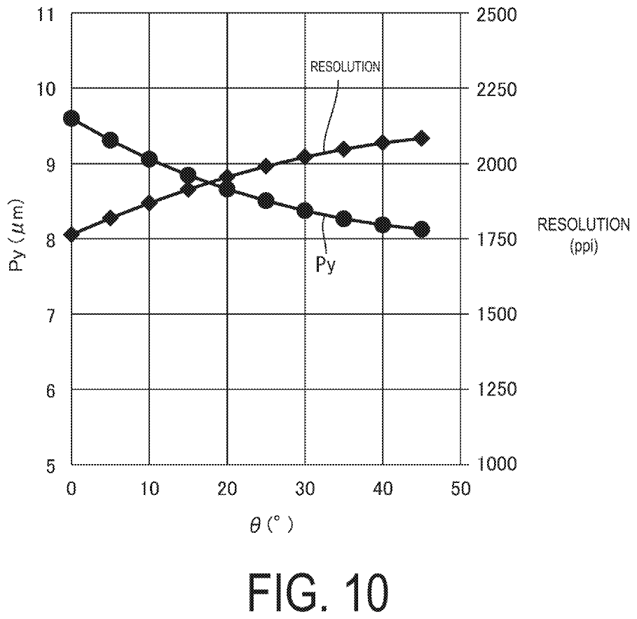

FIG. 10 shows calculation results of the arrangement interval Py between the pixels PX in the Y-axis direction and the resolution. FIG. 10 is a graph in which the horizontal axis represents an angle θ (unit is “°”) formed by the first line segment LS1 and the second line segment LS2 with respect to the Y-axis direction, and the vertical axis represents the arrangement interval Py (unit is “μm”) between the pixels PX in the Y-axis direction and a resolution (unit is “ppi”). The vertical axis on the left side in FIG. 10 represents the arrangement interval Py, and the vertical axis on the right side represents the resolution. According to FIG. 10, when “θ=0°”, the numerical value of Py is approximately “9.6 μm”, and the numerical value of the resolution is approximately “1763 ppi”. According to FIG. 10, it can be understood that as the value of θ increases from 0°, the numerical value of Py tends to decrease and the numerical value of the resolution tends to increase. According to the results in FIG. 9, θ is preferably approximately 40°. Thus, referring to the plot where θ is 40° in FIG. 10, the numerical value of Py is approximately “8.2 μm”, and the resolution is approximately “2068 ppi”. Thus, when θ is set to 40°, it is possible to improve the resolution from approximately “1763 ppi” to approximately “2068 ppi” as compared to when θ is 0°, and to achieve high definition.

In the present embodiment, as illustrated in FIGS. 3 and 6, the drain electrode 27C is disposed such that a portion of the drain electrode 27C overlaps at least a portion of the first bent portion 25C, the pixel electrode 28 is disposed such that a portion of the pixel electrode 28 overlaps both at least a portion of the first bent portion 25C and a portion of the drain electrode 27C, and the third contact hole CH3 connecting the drain electrode 27C and the pixel electrode 28 is provided at a position overlapping both the drain electrode 27C and the pixel electrode 28 in the first flattening film 35. In this manner, the third contact hole CH3 connecting the drain electrode 27C and the pixel electrode 28 overlaps at least a portion of the first bent portion 25C. That is, since the third contact hole CH3 overlaps a portion of the gate wiring line 25 that does not contribute to display, it is possible to avoid a reduction in the aperture ratio of the pixel PX due to the third contact hole CH3. This is more advantageous for achieving high definition.

In the present embodiment, a COA structure is adopted in which the color filter 29 is provided on the array substrate 21 so as to overlap the pixel electrode 28. Thus, compared to a case where the pixel electrode 28 and the color filter 29 that configure the pixel PX overlap each other by providing the color filter 29 on the counter substrate 20 and bonding the array substrate 21 to the counter substrate 20, the pixel electrode 28 and the color filter 29 can be positioned with high definition. Thereby, it is possible to achieve higher definition.

As described above, the array substrate 21 of the present embodiment includes the semiconductor portion 27D configured with a portion of the semiconductor film, the gate insulating film (first insulating film) 32 disposed on the upper layer side of the semiconductor film, the gate wiring line (first wiring line) 25 configured with a portion of the second metal layer (first conductive layer) disposed on the upper layer side of the gate insulating film 32, the second interlayer insulating film 33 and the third interlayer insulating film 34 which are second insulating films disposed on the upper layer side of the second metal layer, and the drain electrode (first electrode) 27C configured with a portion of the first transparent electrode film (second conductive layer) disposed on the upper layer side of the third interlayer insulating film 34 which is the second insulating film. The drain electrode 27C is disposed at a position spaced apart from the gate wiring line 25 in a first direction in such a manner that at least a portion overlaps a portion of the semiconductor portion 27D, the first contact hole CH1 connecting the semiconductor portion 27D and the drain electrode 27C is provided at a position overlapping both the semiconductor portion 27D and the drain electrode 27C in the gate insulating film 32, and the second interlayer insulating film 33 and the third interlayer insulating film 34, which are second insulating films, and the gate wiring line 25 is configured to include the first bent portion 25C that is bent to be recessed toward the first contact hole CH1 in a plan view so that a portion of the gate wiring line 25 overlaps the first contact hole CH1 in the first direction.

The drain electrode 27C is disposed at a position spaced apart from the gate wiring line 25 in the first direction in such a manner that at least a portion overlaps a portion of the semiconductor portion 27D, and is connected to the semiconductor portion 27D through the first contact hole CH1 provided in the gate insulating film 32, and the second interlayer insulating film 33 and the third interlayer insulating film 34 which are second insulating films. By providing a gap between the first contact hole CH1 and the gate wiring line 25 in this manner, a short circuit between the gate wiring line 25 and the drain electrode 27C through the first contact hole CH1 is avoided. The gate wiring line 25 is configured to include the first bent portion 25C that is bent to be recessed toward the first contact hole CH1 in a plan view so that a portion of the gate wiring line 25 overlaps the first contact hole CH1 in the first direction, and thus it is possible to narrow a range occupied by the gate wiring line 25 and the first contact hole CH1 in a plan view in the first direction while ensuring a sufficient gap between the first contact hole CH1 and the gate wiring line 25. This is advantageous for achieving high definition.

The gate wiring line 25 is configured such that the first line segment (line segment) LS1 connecting the first contact hole CH1 and the gate wiring line 25 at the shortest distance intersects the first bent portion 25C and is inclined with respect to the first direction. When the length of the first line segment LS1 connecting the first contact hole CH1 and the gate wiring line 25 at the shortest distance is assumed to be “S1”, a distance in the first direction from an intersection between the first line segment LS1 and the first contact hole CH1 to an intersection between the first line segment LS1 and the gate wiring line 25 is assumed to be “D1”, and an angle formed by the first line segment LS1 with respect to the first direction is assumed to be “θ1”, “D1=S1·cosθ1” is established. A relationship in which the first line segment LS1 connecting the first contact hole CH1 and the gate wiring line 25 at the shortest distance intersects the first bent portion 25C and is inclined with respect to the first direction is expressed as “0°<θ1<90°”. When the θ1 is substituted into “D1=S1·cosθ1”, the relationship “D1<S1” is obtained. Thus, compared to a case where the first line segment LS1 is parallel to the first direction, that is, when “θ1=0°”, the first contact hole CH1 can be disposed closer to the gate wiring line 25 in the first direction by the amount of “D1−S1”. Thereby, the range occupied by the gate wiring line 25 and the first contact hole CH1 in the first direction in a plan view can be narrowed, which is advantageous for achieving high definition.

The second insulating film includes the second interlayer insulating film (lower-layer-side second insulating film) 33 and the third interlayer insulating film (upper-layer-side second insulating film) 34 located on the upper layer side of the second interlayer insulating film 33. The source wiring line (second wiring line) 26 extending in the first direction is provided to be configured with a portion of the third metal layer (third conductive layer) that is disposed on the lower layer side of the third interlayer insulating film 34 on the upper layer side of the second interlayer insulating film 33. The semiconductor portion 27D is disposed at a position spaced apart from the gate wiring line 25 in the first direction in such a manner that a portion of the semiconductor portion 27D overlaps a portion of the source wiring line 26. The second contact hole CH2 connecting the semiconductor portion 27D and the source wiring line 26 is provided at a position overlapping both the semiconductor portion 27D and the source wiring line 26 in the gate insulating film 32 and the second interlayer insulating film 33. The gate wiring line 25 is configured to include the second bent portion 25D that is bent to be recessed toward the second contact hole CH2 in a plan view so that a portion of the gate wiring line 25 overlaps the second contact hole CH2 in the first direction. The semiconductor portion 27D is disposed at a position spaced apart from the gate wiring line 25 in the first direction in such a manner that at least a portion overlaps a portion of the source wiring line 26, and is connected to the source wiring line 26 through the second contact hole CH2 provided in the gate insulating film 32 and the second interlayer insulating film 33. By providing a gap between the second contact hole CH2 and the gate wiring line 25 in this manner, a short circuit between the gate wiring line 25 and the source wiring line 26 through the second contact hole CH2 is avoided. The gate wiring line 25 is configured to include the second bent portion 25D that is bent to be recessed toward the second contact hole CH2 in a plan view so that a portion of the gate wiring line 25 overlaps the second contact hole CH2 in the first direction, and thus it is possible to narrow a range occupied by the gate wiring line 25 and the second contact hole CH2 in the first direction in a plan view while ensuring a sufficient gap between the second contact hole CH2 and the gate wiring line 25. This is advantageous for achieving high definition.

Furthermore, the gate wiring line 25 is configured such that the second line segment (line segment) LS2 connecting the second contact hole CH2 and the gate wiring line 25 at the shortest distance intersects the second bent portion 25D and is inclined with respect to the first direction. When the length of the second line segment LS2 connecting the second contact hole CH2 and the gate wiring line 25 at the shortest distance is assumed to be “S2”, a distance in the first direction from an intersection between the second line segment LS2 and the second contact hole CH2 to an intersection between the second line segment LS2 and the gate wiring line 25 is assumed to be “D2”, and an angle formed by the second line segment LS2 with respect to the first direction is assumed to be “θ2”, “D2=S2·cosθ2” is established. A relationship in which the second line segment LS2 connecting the second contact hole CH2 and the gate wiring line 25 at the shortest distance intersects the second bent portion 25D and is inclined with respect to the first direction is expressed as “0°<θ2<90°”. When the θ2 is substituted into “D2=S2·cosθ2”, the relationship “D2<S2” is obtained. Thus, compared to a case where the second line segment LS2 is parallel to the first direction, that is, “θ2=0°”, the second contact hole CH2 can be disposed closer to the gate wiring line 25 in the first direction by the amount of “D2−S2”. Thereby, the range occupied by the gate wiring line 25 and second contact hole CH2 in the first direction in a plan view can be narrowed, which is advantageous for achieving high definition.

The first bent portion 25C and the second bent portion 25D have planar shapes that are symmetrical to each other. This facilitates the design of the gate wiring line 25. The angle θ1 formed by the first line segment LS1 connecting the first contact hole CH1 and the gate wiring line 25 at the shortest distance with respect to the first direction is equal to the angle θ2 formed by the second line segment LS2 connecting the second contact hole CH2 and the gate wiring line 25 at the shortest distance with respect to the first direction.

The pixel electrodes (second electrodes) 28 connected to the drain electrodes 27C to configure the pixel PX, which is the display unit, are provided. When the angle formed by the first line segment LS1 connecting the first contact hole CH1 and the gate wiring line 25 at the shortest distance with respect to the first direction is assumed to be “θ1”, the line width of gate wiring lines 25 is assumed to be “L”, the dimension of the range occupied by gate wiring lines 25 in the first direction in a plan view is assumed to be “W”, an arrangement interval between the pixels PX in the first direction is assumed to be “Py”, and an arrangement interval between the pixels PX in a second direction orthogonal to the first direction is assumed to be “Px”, the angle θ1 satisfies the relationship “W=Px/2·tanθ1+L/cosθ1<Py/2”. Signals transmitted by the source wiring lines 26 are supplied to the pixel electrodes 28 configuring the pixels PX via the semiconductor portion 27D and the drain electrode 27C, and thus it is possible to perform display of the pixels PX with a gradation based on the signals. On the other hand, the range occupied by the gate wiring lines 25 in the first direction in a plan view is a range that does not contribute to display. The dimension W of the range occupied by the gate wiring line 25 in the first direction in a plan view can be expressed by the equation “W=Px/2·tanθ1+L/cosθ1”. By setting the angle θ1 so as to satisfy the relationship “W<Py/2”, the range occupied by the pixels PX, which are components that contribute to display, in the first direction in a plan view can be made at least twice the range occupied by the gate wiring lines 25, which do not contribute to display, in the first direction in a plan view. This makes it possible to maintain a sufficiently high aperture ratio of the pixel PX, which is more preferable for achieving high definition.

The pixel electrode 28 is provided to be configured with the first flattening film (third insulating film) 35 disposed on the upper layer side of the first transparent electrode film and a portion of the second transparent electrode film (fourth conductive layer) disposed on the upper layer side of the first flattening film 35, and to configure a pixel PX, which is a display unit. The drain electrode 27C is disposed such that a portion of the drain electrode 27C overlaps at least a portion of the first bent portion 25C, and the pixel electrode 28 is disposed such that a portion of the pixel electrode 28 overlaps both at least a portion of the first bent portion 25C and a portion of the drain electrode 27C. The third contact hole CH3 connecting the drain electrode 27C and the pixel electrode 28 is provided at a position overlapping both the drain electrode 27C and the pixel electrode 28 in the first flattening film 35. A portion of the pixel electrode 28 overlaps a portion of the drain electrode 27C, and is connected to the drain electrode 27C through the third contact hole CH3 provided in the first flattening film 35. The third contact hole CH3 connecting the drain electrode 27C and the pixel electrode 28 overlaps at least a portion of the first bent portion 25C. That is, since the third contact hole CH3 overlaps a portion of the gate wiring line 25 that does not contribute to display, it is possible to avoid a reduction in the aperture ratio of the pixel PX due to the third contact hole CH3. This is more advantageous for achieving high definition.

There are provided the pixel electrode 28 connected to the drain electrode 27C to configure the pixel PX, which is a display unit, and the color filter 29 disposed to overlap the pixel electrode 28. Compared to a case where the pixel electrode 28 and the color filter 29 that configure the pixel PX overlap each other by providing the color filter 29 on the counter substrate 20, which is a substrate different from the array substrate 21, and bonding the array substrate 21 to the counter substrate 20 which is another substrate, the pixel electrode 28 and the color filter 29 can be positioned with high definition. Thereby, it is possible to achieve higher definition.

The liquid crystal panel (display device) 11 according to the present embodiment includes the array substrate 21 described above and the counter substrate 20 that faces the array substrate 21. According to such a liquid crystal panel 11, high definition can be achieved in the array substrate 21, thereby improving the display quality of images.

### Second Embodiment

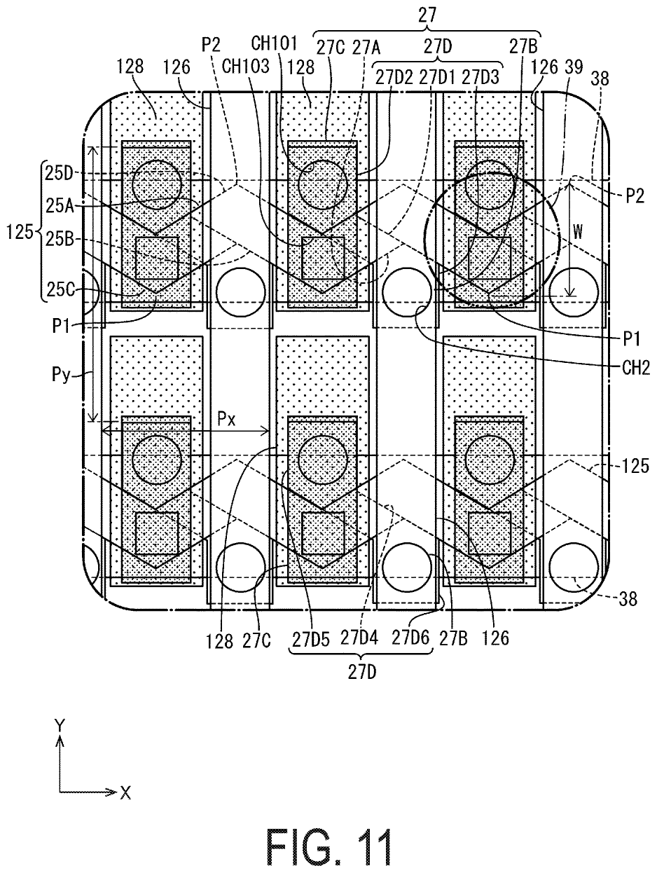

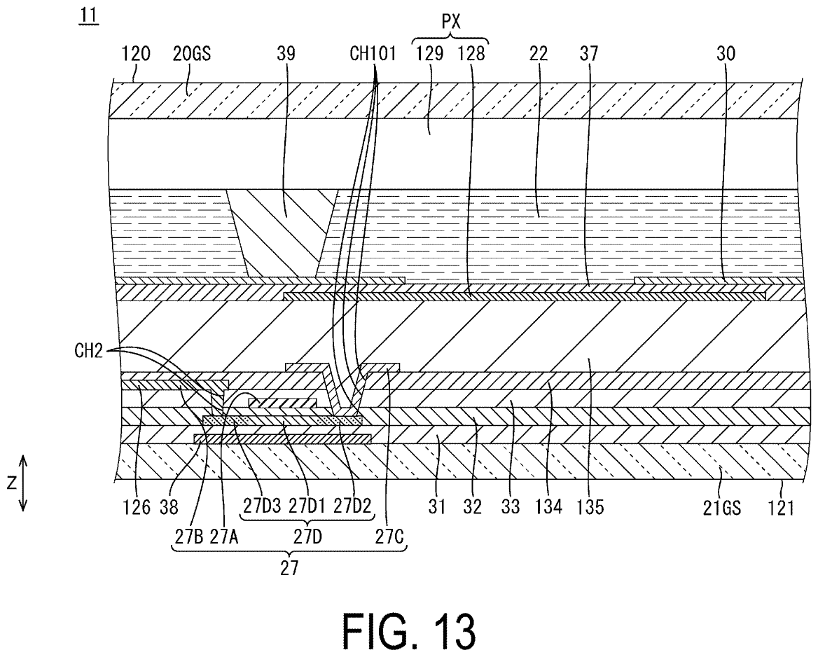

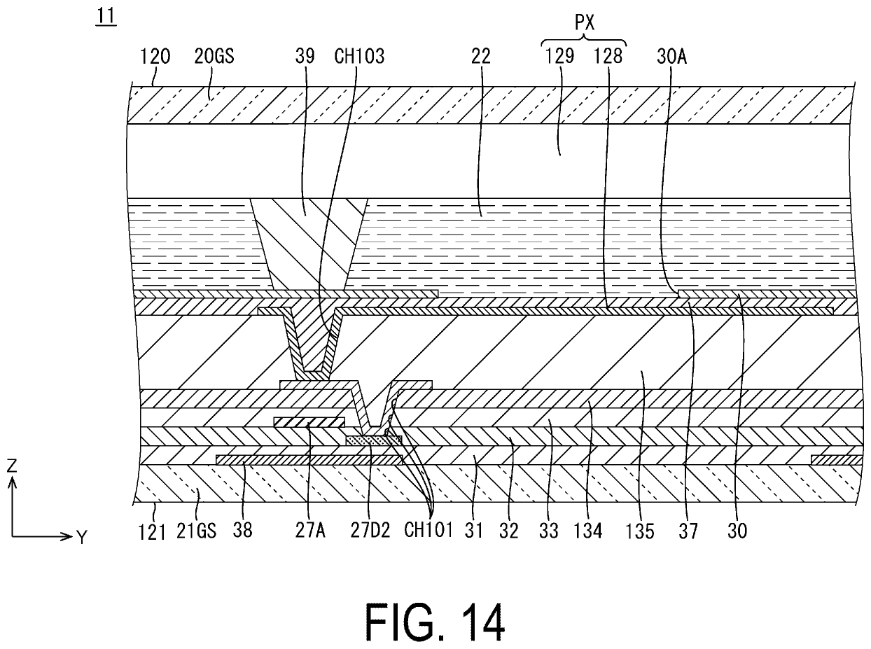

A second embodiment will be described with reference to FIGS. 11 to 17. In the second embodiment, a case where a color filter 129 is provided on a counter substrate 120 is described. Further, repetitive descriptions of structures, actions, and effects similar to those of the first embodiment described above will be omitted.

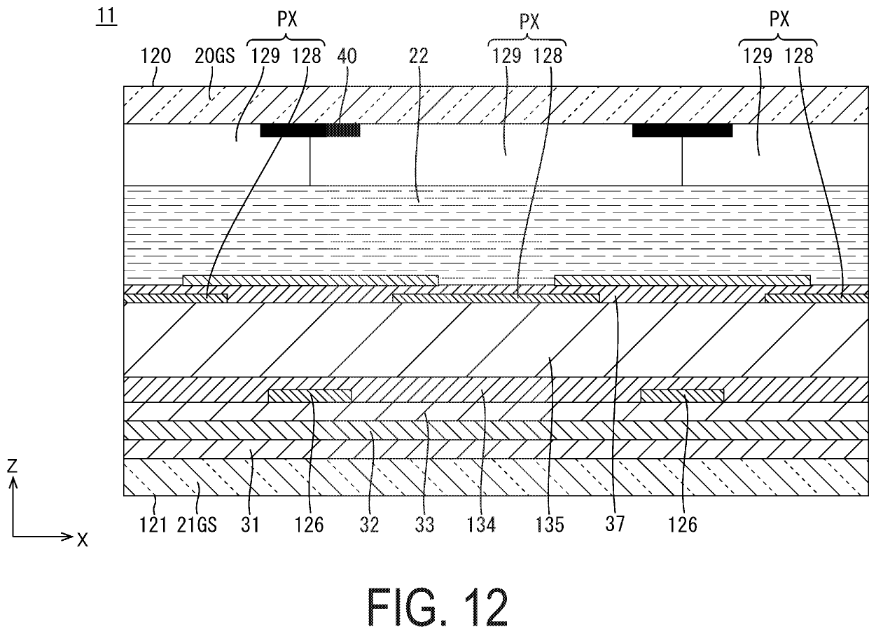

As illustrated in FIGS. 11 and 12, the array substrate 121 according to the present embodiment does not include the color filter 129. The color filter 129 is provided on the counter substrate 120. In addition to the color filter 129, the counter substrate 120 is provided with second light-shielding portions 40 located at boundaries between a plurality of color filters 129 that exhibit different colors. The second light-shielding portions 40 can curb color mixing between pixels PX that exhibit different colors.

As illustrated in FIGS. 12 to 14, an array substrate 121 that does not include the color filter 129 has a first flattening film 135 disposed on the upper layer side of a third interlayer insulating film 134. A third contact hole CH103 is provided only in the first flattening film 135, and its depth is substantially the same as the film thickness of the first flattening film 135. In the present embodiment, the depth of the third contact hole CH103 is smaller than in the first embodiment, and thus a second flattening film 36 that fills the third contact hole CH3 as in the first embodiment is omitted (see FIG. 6).

A pixel electrode 128 according to the present embodiment also differs from that in the first embodiment in that a ratio of a short side dimension to a long side dimension is, for example, “1:2”, as illustrated in FIG. 11. The short side dimension of the pixel electrode 128 matches an arrangement interval Px between pixels PX in the X-axis direction, and the long side dimension of the pixel electrode 128 matches an arrangement interval Py between the pixels PX in the Y-axis direction.

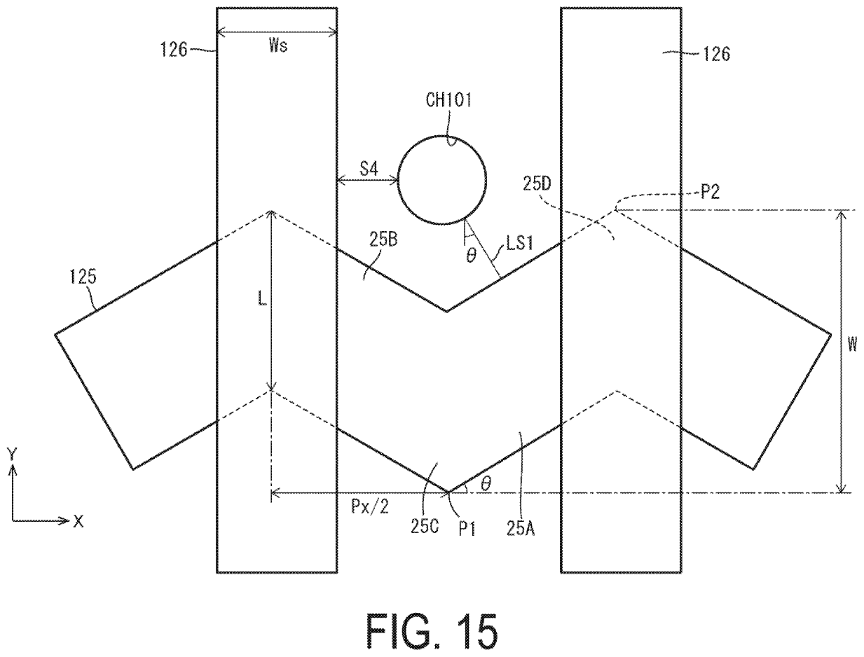

Next, as illustrated in FIG. 15, specific calculations were performed to determine how the arrangement interval Py between the pixels PX in the Y-axis direction and a dimension W of a range occupied by gate wiring lines 125 in the Y-axis direction in a plan view change depending on an angle θ formed by a first line segment LS1 and a second line segment LS2 with respect to the Y-axis direction. The arrangement interval Py between the pixels PX in the Y-axis direction was calculated by substituting specific numerical values into an equation “Py=M1+R1+(R1+S1)·cosθ+G+(R2+S2)·cosθ+M2+R2+S3”. Similarly, the dimension W of the range occupied by the gate wiring lines 125 in the Y-axis direction in a plan view was calculated by substituting specific numerical values into an equation “W=Px/2·tanθ+L/cosθ”. Here, the numerical values of M1 and M2 are each set to 0.5 μm, the numerical values of R1 and R2 are each set to 0.9 μm, the numerical values of S1 and S2 are each set to 1 μm, the numerical value of S3 is set to 2 μm, and the numerical value of L is set to 2.5 μm. In the present embodiment, the numerical value of L is approximately 2.5 times larger than in the first embodiment. In the present embodiment, the ratio of the short side dimension to the long side dimension of the pixel electrode 128 is “1:2”, and thus “Px=Py/2”. That is, the ratio of the numerical value of Px to the numerical value of Py is smaller than in the first embodiment. For this reason, the numerical value of Px needs to be equal to or greater than the minimum value that sufficiently ensures both a line width Ws of a source wiring line 126 and an interval S4 between the source wiring line 126 and the first contact hole CH101. Specifically, when the line width Ws of the source wiring line 126 is set to 1.6 μm and the interval S4 between the source wiring line 126 and the first contact hole CH101 is set to 0.8 μm (R1 is 0.9 μm), the minimum value of Px is “5 μm”. The numerical value of G can also be calculated based on “G=L·cosθ”.

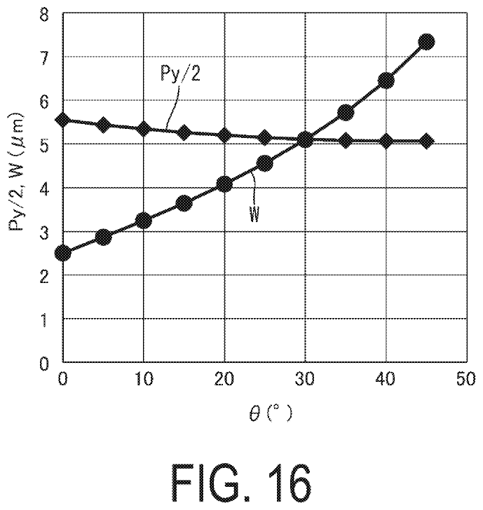

FIG. 16 shows calculation results of the arrangement interval Py between the pixels PX in the Y-axis direction and the dimension W of the range occupied by the gate wiring lines 125 in the Y-axis direction in a plan view. FIG. 16 is a graph in which the horizontal axis represents an angle θ (unit is “°”) formed by the first line segment LS1 and the second line segment LS2 with respect to the Y-axis direction, and the vertical axis represents a value obtained by dividing the arrangement interval Py between the pixels PX in the Y-axis direction by 2 (Py/2: unit is “μm”) and the dimension W (unit is “μm”) of the range occupied by the gate wiring lines 125 in the Y-axis direction in a plan view. According to FIG. 16, when “θ=0°”, the numerical value of Py/2 is approximately “5.55 μm”, and the numerical value of W is approximately “2.5 μm”. According to FIG. 16, it can be understood that as the value of θ increases from 0°, the numerical value of Py/2 tends to decrease and the numerical value of W tends to increase. In FIG. 16, an intersection between the calculation result of Py/2 and the calculation result of W indicates that “W=Py/2”. Thus, when θ is set to a value smaller than the intersection between the calculation result of Py/2 and the calculation result of W, the relationship “W=Px/2·tanθ+L/cosθ<Py/2” is satisfied. According to FIG. 16, it is preferable to set θ to 30° or less, and setting θ to approximately 30° is preferable for achieving both high definition and a high aperture ratio. Referring to the plot where θ is 30°, the numerical value of Py/2 is approximately “5.1 μm”, and the numerical value of W is approximately “5.1 μm”, which is close to the numerical value of Py/2, but the numerical value of W is slightly smaller.

Next, specific calculations were performed to determine how the arrangement interval Py between the pixels PX in the Y-axis direction, an arrangement interval Px between the pixels PX in the X-axis direction, and a resolution change depending on the angle θ formed by the first line segment LS1 and the second line segment LS2 with respect to the Y-axis direction. The arrangement interval Py between the pixels PX in the Y-axis direction was calculated in the same manner as above. The arrangement interval Px between the pixels PX in the X-axis direction was calculated based on the arrangement interval Py. Regarding the resolution, the number of pixels per inch (ppi) was calculated based on the arrangement interval Py between the pixels PX in the Y-axis direction and the arrangement interval Px between the pixels PX in the X-axis direction.

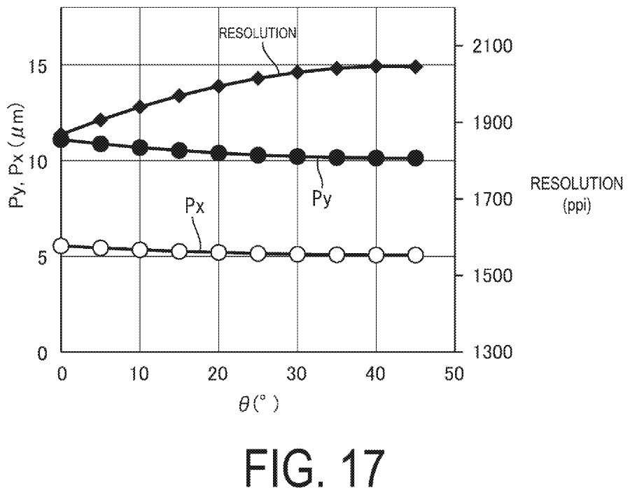

FIG. 17 shows calculation results of the arrangement interval Py between the pixels PX in the Y-axis direction, the arrangement interval Px between the pixels PX in the X-axis direction, and the resolution. FIG. 17 is a graph in which the horizontal axis represents an angle θ (unit is “°”) formed by the first line segment LS1 and the second line segment LS2 with respect to the Y-axis direction, and the vertical axis represents the arrangement interval Py (unit is “μm”) between the pixels PX in the Y-axis direction, the arrangement interval Px (unit is “μm”) between the pixels PX in the X-axis direction, and a resolution (unit is “ppi”). The vertical axis on the left side in FIG. 17 represents the arrangement interval Py and the arrangement interval Px, and the vertical axis on the right side represents the resolution. According to FIG. 17, when “θ=0°”, the numerical value of Py is approximately “11.1 μm”, the numerical value of Px is approximately “5.55 μm”, and the numerical value of the resolution is approximately “1868 ppi”. According to FIG. 17, it can be understood that as the value of θ increases from 0°, the numerical values of Py and Px tend to decrease and the numerical value of the resolution tends to increase. According to the results in FIG. 16, θ is preferably approximately 30°. Thus, referring to the plot where θ is 30° in FIG. 17, the numerical value of Py is approximately “10.2 μm”, the numerical value of Px is approximately “5.1 μm” (equal to or greater than 5 μm), and the resolution is approximately “2030 ppi”. Thus, when θ is set to 30°, it is possible to improve the resolution from approximately “1868 ppi” to approximately “2030 ppi” as compared to when θ is 0°, and to achieve high definition.

### Third Embodiment

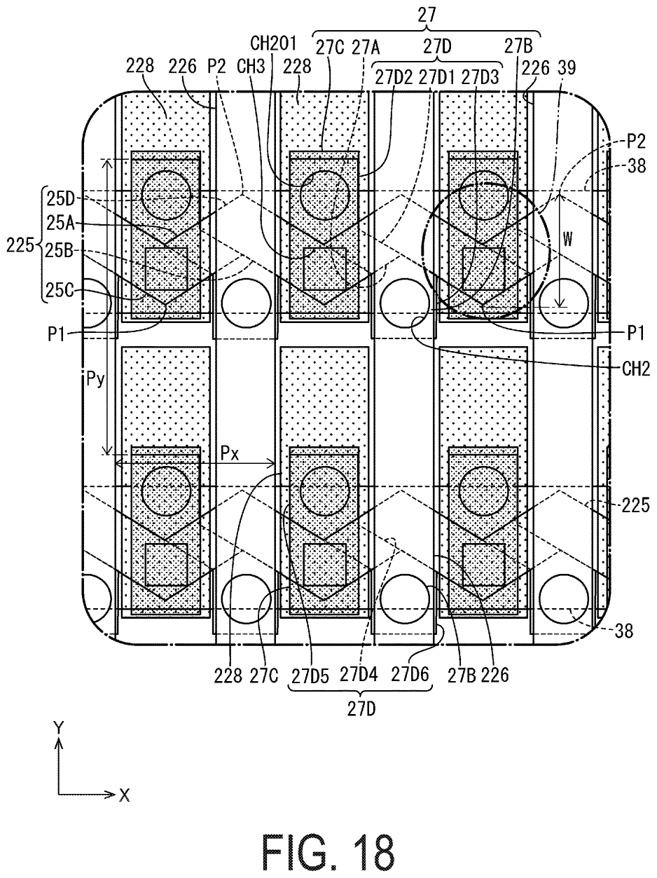

A third embodiment will be described with reference to FIGS. 18 to 21. The third embodiment shows a case where a ratio of a short side dimension to a long side dimension of a pixel electrode 228 is changed from that in the second embodiment described above. Further, repetitive descriptions of structures, actions, and effects similar to those of the second embodiment described above will be omitted.

The pixel electrode 228 according to the present embodiment also differs from that in the first embodiment in that a ratio of a short side dimension to a long side dimension is, for example, “1:3”, as illustrated in FIG. 18. The short side dimension of the pixel electrode 228 matches an arrangement interval Px between pixels PX in the X-axis direction, and the long side dimension of the pixel electrode 228 matches an arrangement interval Py between the pixels PX in the Y-axis direction.

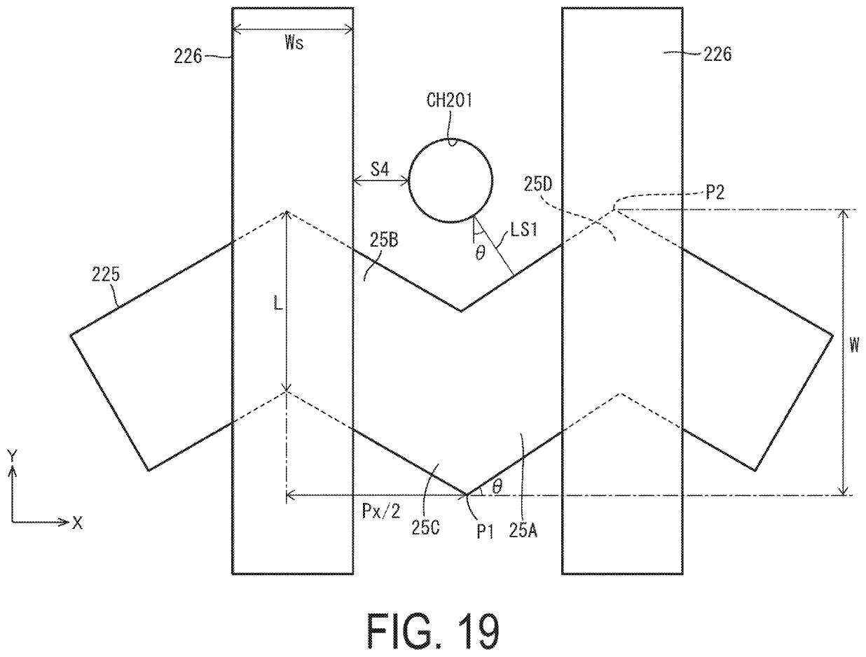

Next, as illustrated in FIG. 19, specific calculations were performed to determine how the arrangement interval Py between the pixels PX in the Y-axis direction and the dimension W of a range occupied by gate wiring lines 225 in the Y-axis direction in a plan view change depending on an angle θ formed by a first line segment LS1 and a second line segment LS2 with respect to the Y-axis direction. The arrangement interval Py between the pixels PX in the Y-axis direction was calculated by substituting specific numerical values into an equation “Py=M1 +R1+(R1+S1)·cosθ+G+(R2+S2)·cosθ+M2+R2+S3”. Similarly, the dimension W of the range occupied by the gate wiring lines 225 in the Y-axis direction in a plan view was calculated by substituting specific numerical values into an equation “W=Px/2·tanθ+L/cosθ”. Here, the numerical values of M1 and M2 are each set to 5 μm, the numerical values of R1 and R2 are each set to 0.9 μm, the numerical values of S1 and S2 are each set to 1 μm, the numerical value of S3 is set to 2 μm, and the numerical value of L is set to 2.5 μm. In the present embodiment, the ratio of the short side dimension to the long side dimension of the pixel electrode 228 is “1:3”, and thus “Px =Py/3”. That is, the ratio of the numerical value of Px to the numerical value of Py is smaller than in the first and second embodiments. For this reason, the numerical value of Px needs to be equal to or greater than the minimum value that sufficiently ensures both a line width Ws of a source wiring line 226 and an interval S4 between the source wiring line 226 and a first contact hole CH201. Specifically, when the line width Ws of the source wiring line 226 is set to 1.6 μm and the interval S4 between the source wiring line 226 and the first contact hole CH201 is set to 0.8 μm (R1 is 0.9 μm), the minimum value of Px is “5 μm”. The numerical value of G can also be calculated based on “G=L·cosθ”.

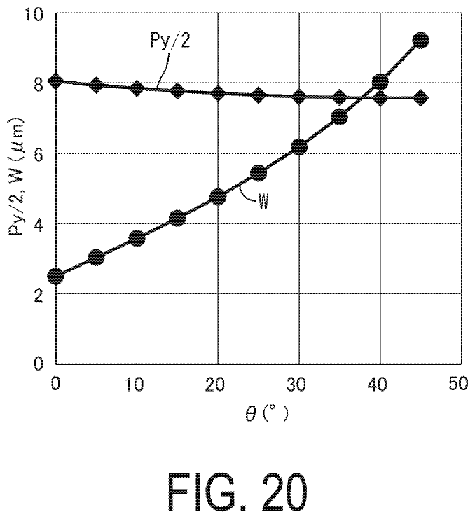

FIG. 20 shows calculation results of the arrangement interval Py between the pixels PX in the Y-axis direction and the dimension W of the range occupied by the gate wiring lines 225 in the Y-axis direction in a plan view. FIG. 20 is a graph in which the horizontal axis represents an angle θ (unit is “°”) formed by the first line segment LS1 and the second line segment LS2 with respect to the Y-axis direction, and the vertical axis represents a value obtained by dividing the arrangement interval Py between the pixels PX in the Y-axis direction by 2 (Py/2: unit is “μm”) and the dimension W (unit is “μm”) of the range occupied by the gate wiring lines 225 in the Y-axis direction in a plan view. According to FIG. 20, when θ=0°, the numerical value of Py/2 is approximately “8.05 μm”, and the numerical value of W is approximately “2.5 μm”. According to FIG. 20, it can be understood that as the value of θ increases from 0°, the numerical value of Py/2 tends to decrease and the numerical value of W tends to increase. In FIG. 20, an intersection between the calculation result of Py/2 and the calculation result of W indicates that “W=Py/2”. Thus, when θ is set to a value smaller than the intersection between the calculation result of Py/2 and the calculation result of W, the relationship “W=Px/2·tanθ+L/cosθ<Py/2” is satisfied. According to FIG. 20, it is preferable to set θ to 35° or less, and setting θ to approximately 35° is preferable for achieving both high definition and a high aperture ratio. Referring to the plot where θ is 35°, the numerical value of Py/2 is approximately “7.58 μm”, and the numerical value of W is approximately “7.03 μm”.

Next, specific calculations were performed to determine how the arrangement interval Py between the pixels PX in the Y-axis direction, an arrangement interval Px between the pixels PX in the X-axis direction, and a resolution change depending on the angle θ formed by the first line segment LS1 and the second line segment LS2 with respect to the Y-axis direction. The arrangement interval Py between the pixels PX in the Y-axis direction was calculated in the same manner as above. The arrangement interval Px between the pixels PX in the X-axis direction was calculated based on the arrangement interval Py. Regarding the resolution, the number of pixels per inch (ppi) was calculated based on the arrangement interval Py between the pixels PX in the Y-axis direction and the arrangement interval Px between the pixels PX in the X-axis direction.

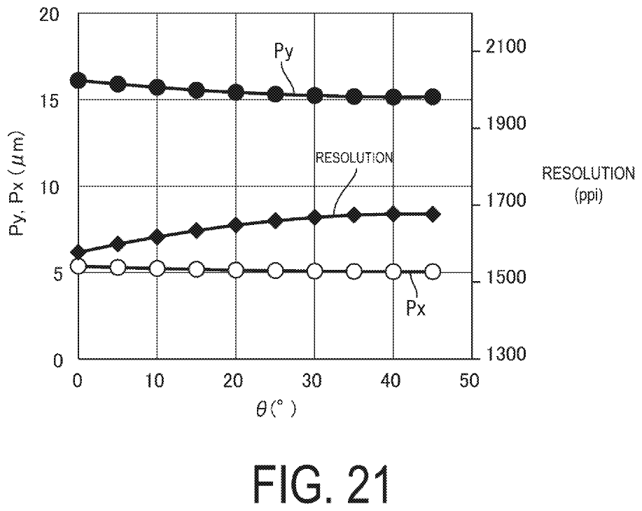

FIG. 21 shows calculation results of the arrangement interval Py between the pixels PX in the Y-axis direction, the arrangement interval Px between the pixels PX in the X-axis direction, and the resolution. FIG. 21 is a graph in which the horizontal axis represents an angle θ (unit is “°”) formed by the first line segment LS1 and the second line segment LS2 with respect to the Y-axis direction, and the vertical axis represents the arrangement interval Py (unit is “μm”) between the pixels PX in the Y-axis direction, the arrangement interval Px (unit is “μm”) between the pixels PX in the X-axis direction, and a resolution (unit is “ppi”). The vertical axis on the left side in FIG. 21 represents the arrangement interval Py and the arrangement interval Px, and the vertical axis on the right side represents the resolution. According to FIG. 21, when “θ=0°”, the numerical value of Py is approximately “16.1 μm”, the numerical value of Px is approximately “5.37 μm”, and the numerical value of the resolution is approximately “1577 ppi”. According to FIG. 21, it can be understood that as the value of θ increases from 0°, the numerical values of Py and Px tend to decrease and the numerical value of the resolution tends to increase. According to the results in FIG. 20, θ is preferably approximately 35°. Thus, referring to the plot where θ is 35° in FIG. 21, the numerical value of Py is approximately “15.1 μm”, the numerical value of Px is approximately “5.05 μm” (equal to or greater than 5 μm), and the resolution is approximately “1674 ppi”. Thus, when θ is set to 35°, it is possible to improve the resolution from approximately “1577 ppi” to approximately “1674 ppi” as compared to when θ is 0°, and to achieve high definition.

### Other Embodiments

The techniques disclosed herein are not limited to the embodiments described above and illustrated in the drawings, and the following embodiments, for example, are also included within the technical scope.

(1) The specific planar shapes of the gate wiring lines 25, 125, and 225 can be changed as appropriate to shapes other than those illustrated in the drawings. For example, the gate wiring lines 25, 125, and 225 may have portions that extend non-linearly in directions oblique to the X-axis and Y-axis directions, and specifically may have portions that are curved in an arc shape or in a non-arc shape. When the gate wiring lines 25, 125, 225 have portions that are curved in an arc shape, the portions may be concentric with the first contact holes CH1, CH101, and CH201 and the second contact holes.

(2) As described in (1) above, when the gate wiring lines 25, 125, and 225 have a curved portion, the planar shapes of the first bent portion 25C and the second bent portion 25D may be a substantially U-shape or a substantially inverted U-shape.

(3) The gate wiring lines 25, 125, and 225 may be configured such that the planar shapes of the first bent portion 25C and the second bent portion 25D are asymmetric.

(4) The gate wiring lines 25, 125, and 225 may be configured not to include the second bent portion 25D. That is, the portions of the gate wiring lines 25, 125, and 225 which intersect the source wiring lines 26, 126, and 226 may extend straight in the X-axis direction.

(5) The centers of the first contact holes CH1, CH101, and CH201 may be misaligned in the X-axis direction from the first bent point P1 of the first bent portion 25C. Similarly, the center of the second contact hole CH2 may be misaligned in the X-axis direction from the second bent point P2 of the second bent portion 25D.

(6) A configuration in which the second contact hole CH2 is not provided may be adopted. For example, structures configured with a portion of a semiconductor film are provided in ranges overlapping the source wiring lines 26, 126, and 226, and portions of the structures which do not overlap the gate wiring lines 25, 125, and 225 are made into low-resistance regions, and the low-resistance regions are connected to the source wiring lines 26, 126, and 226. In this manner, the second low-resistance region 27D3 of the semiconductor portion 27D can be connected to the low-resistance regions of the structures which overlap the source wiring lines 26, 126, and 226 without using a contact hole.

(7) In the configurations described in the second and third embodiments, the second light-shielding portion 40 can also be provided on the array substrate 121. For example, the second light-shielding portion 40 can be provided on the common electrode 30 of the array substrate 121.

(8) Specific planar shapes of the contact holes CH1, CH2, CH3, CH101, CH103, and CH201 can be changed as appropriate. For example, the planar shapes of the first contact holes CH1, CH101, and CH201 and the second contact hole CH2 may be rectangular or the like. The planar shapes of the third contact holes CH3 and CH103 may be circular or the like.

(9) The specific numerical values of M1, M2, R1, R2, S1, S2, S3, S4, L, and Ws can also be changed as appropriate to values other than those described above.

(10) The material of the first metal layer can also be MoW (molybdenum tungsten) or the like. The first metal layer may also be a layered film.

(11) As the materials for the second and third metal layers, Ti/Cu (copper)/Ti, Mo/Al/Mo, Mo/Cu/Mo, or the like can be used. The second and third metal layers may also be two-layer layered films or single-layer films.

(12) The film thicknesses of the metal layers may be changed as appropriate to values other than those described above.

(13) As the material for each transparent electrode film, ITO (Indium Tin Oxide) or the like can be used. The film thicknesses of the transparent electrode films can also be changed as appropriate to values other than those described above.

(14) The materials and film thicknesses of the insulating films 31 to 37, 134, and 135 can be changed as appropriate to values other than those described above.

(15) The first circuit portion 14A can be provided on only one side of the display region AA. Instead of the first circuit portion 14A, a gate driver can be attached to the array substrates 21 and 121.

(16) Instead of the second circuit portion 14B, a source driver may be attached to the array substrates 21 and 121.

(17) Instead of the second circuit portion 14B, a source driver may be attached to the flexible substrate 13.

(18) The TFT 27 may be configured as a double-gate type in addition to the top-gate type illustrated in the drawings.

(19) The pixel electrodes 28, 128, and 228 may be disposed on the upper layer side of the common electrode 30. In this case, slits are provided in the pixel electrodes 28, 128, and 228 that are close to the liquid crystal layer 22.

(20) The semiconductor film may be an amorphous silicon thin film or a polycrystalline silicon thin film.

(21) The display mode of the liquid crystal panel 11 may be any of a twisted nematic (TN) mode, a vertical alignment (VA) mode, an in-plane switching (IPS) mode, and the like.

(22) In addition to the liquid crystal panel 11, the display device may also be an organic electro luminescence (EL) display panel or a microcapsule electrophoresis display panel.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An array substrate comprising:
a semiconductor portion configured with a portion of a semiconductor film;
a first insulating film disposed on an upper layer side of the semiconductor film;
a first wiring line configured with a portion of a first conductive layer disposed on an upper layer side of the first insulating film;
a second insulating film disposed on an upper layer side of the first conductive layer; and
a first electrode configured with a portion of a second conductive layer disposed on an upper layer side of the second insulating film,
wherein the first electrode is disposed at a position spaced apart from the first wiring line in a first direction in such a manner that at least a portion of the first electrode overlaps a portion of the semiconductor portion,
a first contact hole connecting the semiconductor portion and the first electrode is provided at a position overlapping both the semiconductor portion and the first electrode in the first insulating film and the second insulating film, and
the first wiring line includes a first bent portion that is bent to be recessed toward the first contact hole in a plan view so that a portion of the first wiring line overlaps the first contact hole in the first direction.

2. The array substrate according to claim 1,
wherein the first wiring line is configured such that a line segment connecting the first contact hole and the first wiring line at a shortest distance intersects the first bent portion and is inclined with respect to the first direction.

3. The array substrate according to claim 1,
wherein the second insulating film includes
a lower-layer-side second insulating film and
an upper-layer-side second insulating film located on an upper layer side of the lower-layer-side second insulating film,
the array substrate includes a second wiring line extending in the first direction, the second wiring line being configured with a portion of a third conductive layer disposed on a lower layer side of the upper-layer-side second insulating film on an upper layer side of the lower-layer-side second insulating film,
the semiconductor portion is disposed at a position spaced apart from the first wiring line in the first direction so that a portion of the semiconductor portion overlaps a portion of the second wiring line,
a second contact hole connecting the semiconductor portion and the second wiring line is provided at a position overlapping both the semiconductor portion and the second wiring line in the first insulating film and the lower-layer-side second insulating film, and
the first wiring line includes a second bent portion that is bent to be recessed toward the second contact hole in a plan view so that a portion of the first wiring line overlaps the second contact hole in the first direction.

4. The array substrate according to claim 3,
wherein the first wiring line is configured such that a line segment connecting the second contact hole and the first wiring line at a shortest distance intersects the second bent portion and is inclined with respect to the first direction.

5. The array substrate according to claim 3,
wherein the first bent portion and the second bent portion have planar shapes symmetrical to each other.

6. The array substrate according to claim 5, further comprising:
a second electrode connected to the first electrode to configure a pixel which is a display unit,
wherein, when an angle formed by a line segment connecting the first contact hole and the first wiring line at a shortest distance with respect to the first direction is assumed to be “θ1”, a line width of the first wiring line is assumed to be “L”, a dimension of a range occupied by the first wiring line in the first direction in a plan view is assumed to be “W”, an arrangement interval of the pixels in the first direction is assumed to be “Py”, and an arrangement interval of the pixels in a second direction orthogonal to the first direction is assumed to be “Px”, the θ1 satisfies a relationship “W=Px/2·tanθ1+L/cosθ1<Py/2”.

7. The array substrate according to claim 1, further comprising:
a third insulating film disposed on an upper layer side of the second conductive layer; and
a second electrode configured with a portion of a fourth conductive layer disposed on an upper layer side of the third insulating film and configuring a pixel which is a display unit,
wherein the first electrode is disposed such that a portion of the first electrode overlaps at least a portion of the first bent portion,
the second electrode is disposed such that a portion of the second electrode overlaps both at least a portion of the first bent portion and a portion of the first electrode, and
a third contact hole connecting the first electrode and the second electrode is provided at a position overlapping both the first electrode and the second electrode in the third insulating film.

8. The array substrate according to claim 1, further comprising:
a second electrode connected to the first electrode to configure a pixel which is a display unit; and
a color filter disposed to overlap the second electrode.

9. A display device comprising:
the array substrate according to claim 1; and
a counter substrate facing the array substrate.
